(19) United States
(12) Patent Application Publication
(10) Pub. No.: US 2016/0035903 A1
(43) Pub. Date: Feb. 4, 2016

(54) THIN-FILM TRANSISTOR

(71) Applicants: SUMITOMO CHEMICAL COMPANY, LIMITED, Tokyo (JP); OSAKA UNIVERSITY, Suita-shi, Osaka (JP)

(72) Inventors: Takayuki OKACHI, Ibaraki (JP); Junichi TAKEYA, Osaka (JP)

(73) Assignees: OSAKA UNIVERSITY, Suita-shi, Osaka (JP); SUMITOMO CHEMICAL COMPANY, LIMITED, Tokyo (JP)

(21) Appl. No.: 14/772,572

(22) PCT Filed: Feb. 26, 2014
(86) PCT No.: PCT/JP2014/054739

§ 371 Date: Sep. 3, 2015

(30) Foreign Application Priority Data
Mar. 6, 2013 (JP) 2013-044708

(51) Int. Cl. H01L 29/786; H01L 29/06

(52) U.S. Cl. CPC H01L 29/78696; H01L 29/0692

(57) ABSTRACT

Thin-film transistor includes column-shaped protrusion portion having a side surface and protruding from a main surface of the substrate, a gate insulating layer including a first layer and a second layer, at least part of the gate insulating layer being in a channel region extending along the side surface, a gate electrode in contact with the gate insulating layer, a source electrode and a drain electrode isolated from one another, at least part of one of the source electrode and the drain electrode overlap the protrusion portion and the other being in a region that does not overlap the protrusion portion or the one electrode, and a semiconductor layer in contact with at least part of the source electrode, at least part of the drain electrode, and at least part of the gate insulating layer in the channel region directly or with a functional layer interposed.

### TECHNICAL FIELD

The present invention relates to a thin-film transistor.

### BACKGROUND ART

In order to drive a display device having organic electroluminescent elements, thin-film transistors that allow larger on-current to flow than conventional thin-film transistors are required. With higher definition of display devices in recent years, there is a demand for thin-film transistors having higher cutoff frequencies and capable of faster response.

Higher charge-carrier mobility of semiconductor materials increases on-current and/or a cutoff frequency. For this reason, semiconductor materials having higher charge-carrier mobility have been developed actively. In particular, organic semiconductor materials and oxide semiconductor materials that allow production of semiconductor layers by coating have drawn attention because they can reduce the production costs. The charge-carrier mobility thereof, however, is not yet satisfactory.

Examples of means for improving on-current and/or a cutoff frequency may include further reducing the channel length of a thin-film transistor, in addition to increasing the charge-carrier mobility of a semiconductor material. It is, however, extremely difficult to set the channel length to, for example, 1 μm or less in terms of ensuring the function of the thin-film transistor. In addition, the production costs are increased because complex steps and expensive manufacturing devices are generally required.

In order to solve such problems, a vertical thin-film transistor is proposed, in which the direction of the channel extension corresponds to the thickness direction of the thin-film transistor (See Patent Documents 1 and 2). In such a conventional vertical thin-film transistor, because the side surface of a step provided on the substrate is used as the channel, the channel length can be controlled by changing the height of the step. Thus, the channel length can be set to 1 μm or less.

### RELATED ART DOCUMENTS

### Patent Document

Patent Document 1: JP 2008-270687 A

Patent Document 2: JP 2008-34760 A

### DISCLOSURE OF INVENTION

### Problem to be Solved by the Invention

When the channel length of a thin-film transistor is to be reduced, it is generally necessary to reduce the thickness of the gate insulating film at the same time in order to achieve predetermined electrical characteristics.

In the vertical type transistor described in Patent Documents above, however, it is particularly difficult to further reduce the thickness of the gate insulating film because of the constraints of the material used and in terms of steps of manufacturing. As a result, there are problems that the on-current and the on/off ratio of the thin-film transistor are reduced, and that the drive voltage is increased.

The present invention is made in terms of such problems and aims to provide a vertical type thin-film transistor (integrated thin-film transistor) having even higher on-current and on/off ratio and capable of being driven with lower voltage.

### Means for Solving Problem

The present invention provides [1] to [14] below.

[1] A thin-film transistor provided on a substrate, comprising:

a column-shaped protrusion portion that protrudes from a main surface of the substrate, the protrusion portion having a side surface extending in a direction that approximately corresponds to a thickness direction of the substrate;

a gate insulating layer with a thickness of 50 nm or less, at least part of the gate insulating layer being provided in a channel region extending along the side surface, the gate insulating layer comprising a first layer that is a metal oxide layer, a metal nitride layer, a silicon oxide layer, or a silicon nitride layer and a second layer that is a self-assembled monomolecular layer;

a gate electrode in contact with the gate insulating layer;

a source electrode and a drain electrode isolated from each other, at least part of one of the source electrode and the drain electrode being provided to overlap the protrusion portion when viewed from the thickness direction of the substrate and the other being provided in a region that does not overlap the protrusion portion or the one electrode when viewed from the thickness direction of the substrate; and

a semiconductor layer in contact with at least part of the source electrode, at least part of the drain electrode, and at least part of the gate insulating layer in the channel region directly or with a functional layer interposed.

[2] The thin-film transistor according to above [1], wherein

the protrusion portion is an insulating structure provided on the substrate,

the gate electrode covers at least part of a side surface of the insulating structure,

the gate insulating layer covers the gate electrode,

the source electrode and the drain electrode are in contact with the gate insulating layer, and

the semiconductor layer covers the source electrode and the drain electrode as well as the gate insulating layer.

[3] The thin-film transistor according to above [1], wherein

the protrusion portion is an insulating structure provided on the substrate,

the gate electrode covers the insulating structure,

the gate insulating layer covers the gate electrode,

the semiconductor layer covers the gate insulating layer, and the source electrode and the drain electrode are in contact with the semiconductor layer.

[4] The thin-film transistor according to above [1], wherein

the protrusion portion is a gate electrode provided on the substrate, and

the gate insulating layer covers the gate electrode.

[5] The thin-film transistor according to above [1], wherein

the protrusion portion is a semiconductor layer provided on the substrate, the gate insulating layer is provided to cover at least part of a side surface of the semiconductor layer, and the gate electrode covers the gate insulating layer.

[6] A thin-film transistor provided on a substrate, comprising:

a column-shaped protrusion portion that protrudes from a main surface of the substrate, the protrusion portion having a side surface with a shorter direction that approximately corresponds to a thickness direction of the substrate and a longer direction that is a direction orthogonal to the thickness direction of the substrate;

a source electrode and a drain electrode isolated from each other, one of the source electrode and the drain electrode being provided to overlap the protrusion portion when viewed from the thickness direction of the substrate and the other being provided in a region that does not overlap the protrusion portion or the one electrode when viewed from the thickness direction of the substrate;

a semiconductor layer that covers the source electrode and the drain electrode as well as the side surface exposed from the source electrode and the drain electrode;

a gate insulating layer with a thickness of about 50 nm or less that covers the semiconductor layer, the gate insulating layer comprising a first layer that is a metal oxide layer, a metal nitride layer, a silicon oxide layer, or a silicon nitride layer and a second layer that is a self-assembled monomolecular layer; and

a gate electrode that is in contact with the gate insulating layer and extends across the protrusion portion.

[7] The thin-film transistor according to above [6], wherein the semiconductor layer covers the substrate and the protrusion portion provided on the substrate, the source electrode and the drain electrode are in contact with the semiconductor layer, and the gate insulating layer covers the source electrode and the drain electrode as well as the semiconductor layer exposed from the source electrode and the drain electrode.
[8] The thin-film transistor according to any one of above [1] to [7], wherein the insulating structure, the gate electrode, or the semiconductor layer is formed through a patterning step by a photolithography method or a nanoimprinting method.
[9] The thin-film transistor according to any one of above [1] to [8], wherein the gate electrode contains metal or silicon, and the metal oxide layer, the metal nitride layer, the silicon oxide layer, and the silicon nitride layer as the first layer are layers formed by subjecting the metal or silicon contained in the gate electrode to plasma treatment or anodic oxidation treatment.
[10] The thin-film transistor according to any one of above [1] to [9], wherein the second layer is a film of a compound that comprises a saturated hydrocarbon group with the number of carbon atoms of 10 or more, or a saturated hydrocarbon group with the number of carbon atoms of 10 or more and optionally having a substituent, and can be bonded to the first layer.
[11] The thin-film transistor according to any one of above [1] to [10], wherein the second layer is a film of a phosphonic acid derivative, a film of a trichlorosilane derivative, or a film of triethoxysilane derivative.
[12] The thin-film transistor according to any one of above [1] to [11], wherein the gate electrode contains aluminum.
[13] An integrated thin-film transistor comprising a plurality of thin-film transistors of any one of above [1] to [12] arranged on the substrate so as to be spaced apart from each other, wherein each gate electrode, each source electrode, and each drain electrode of each of the thin-film transistors are electrically connected to other gate electrodes, other source electrodes, and other drain electrodes, respectively, and the thin-film transistors are integrally operated as a single transistor.
[14] The thin-film transistor according to any one of above [1] to [13], further comprising connection wiring that extends outside a thin-film transistor-formed region where the thin-film transistor is provided when viewed from the thickness direction of the substrate and is connected with each of the source electrode and the drain electrode, wherein the gate electrode and the gate insulating layer have a spread portion that spreads out of the thin-film transistor-formed region when viewed from the thickness direction of the substrate.

### Effect of the Invention

The present invention can provide a thin-film transistor having high on-current and on/off ratio and capable of being driven with low voltage.

### BRIEF DESCRIPTION OF DRAWINGS

FIG. 1-1 is a schematic plan view of a thin-film transistor in a first embodiment.

FIG. 1-2 is a schematic sectional view of the thin-film transistor in the first embodiment.

FIG. 2-1 is a schematic plan view of a thin-film transistor in a second embodiment.

FIG. 2-2 is a schematic sectional view of the thin-film transistor in the second embodiment.

FIG. 3 is a schematic sectional view of a thin-film transistor in a third embodiment.

FIG. 4 is a schematic sectional view of a thin-film transistor in a fourth embodiment.

FIG. 5 is a schematic sectional view of a thin-film transistor in a fifth embodiment.

FIG. 6 is a schematic sectional view of a thin-film transistor in a sixth embodiment.

FIG. 7 is a schematic sectional view of a thin-film transistor in a seventh embodiment.

FIG. 8 is a schematic sectional view of a thin-film transistor in an eighth embodiment.

FIG. 9 is a schematic sectional view of a thin-film transistor in a ninth embodiment.

FIG. 10 is a schematic sectional view of a thin-film transistor in a tenth embodiment.

FIG. 11 is a schematic sectional view of a thin-film transistor in an eleventh embodiment.

FIG. 12-1 is a schematic plan view of a thin-film transistor in a twelfth embodiment.

FIG. 12-2 is a schematic sectional view of the thin-film transistor in the twelfth embodiment.

### DESCRIPTION OF EMBODIMENTS

Preferable embodiments of a thin-film transistor and an integrated thin-film transistor in the present invention will be described below with reference to the figures, if necessary. It should be noted that the figures merely schematically illustrate the shape, size and arrangement of components to the extent that the invention can be understood, and the components in the embodiments can be combined as appropriate without departing from the scope of the present invention.

In the following description of the figures, the same components are denoted with the same letters or numerals and an overlapping description may be omitted. The present invention is not limited by the embodiments described below.

A thin-film transistor in the present invention is provided on a substrate. The thin-film transistor comprises: a column-shaped protrusion portion having a side surface extending in a direction that approximately corresponds to the thickness direction of the substrate and protruding from a main surface of the substrate; a gate insulating layer with a thickness of 50 nm or less, at least part of the gate insulating layer being provided in a channel region extending along the side surface, the gate insulating layer comprising a first layer that is a metal oxide layer, a metal nitride layer, a silicon oxide layer, or a silicon nitride layer and a second layer that is a self-assembled monomolecular layer; a gate electrode in contact with the gate insulating layer; a source electrode and a drain electrode electrically isolated from each other, when viewed from the thickness direction of the substrate, at least part of one of the source electrode and the drain electrode being provided to overlap the protrusion portion and the other being provided in the remaining region; and a semiconductor layer in contact with at least part of the source electrode, at least part of the drain electrode, and at least part of the gate insulating layer in the channel region directly or with a functional layer interposed.

### First Embodiment

### Configuration Example of Thin-Film Transistor

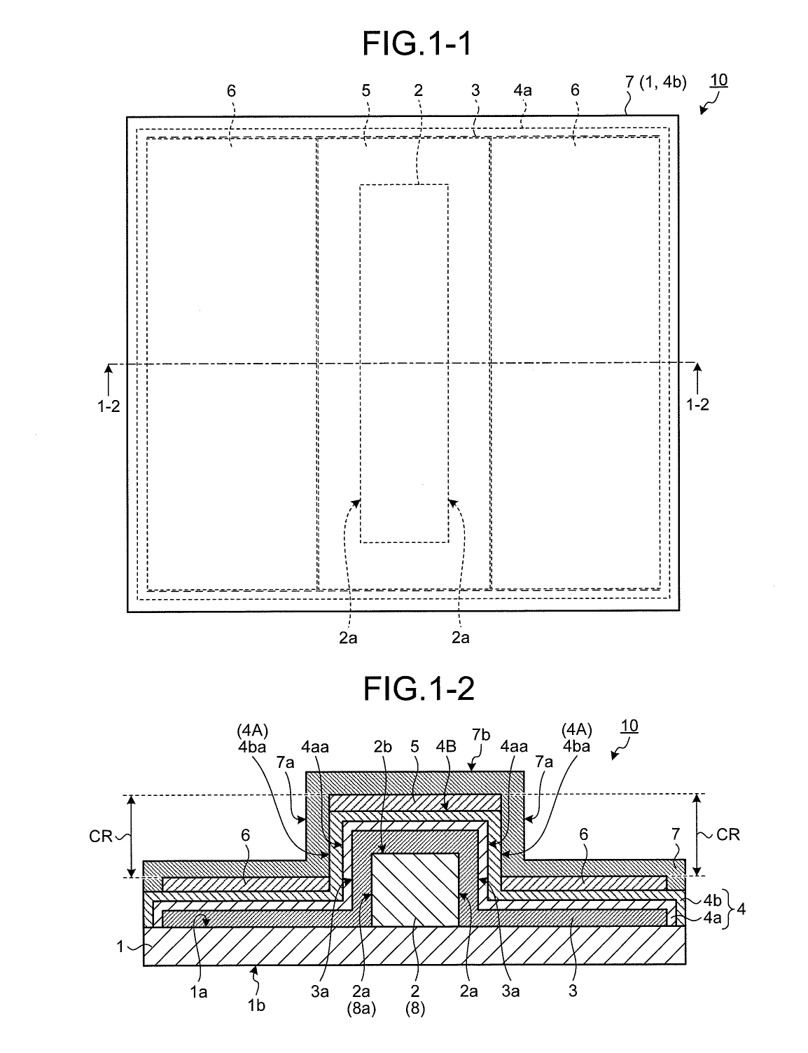

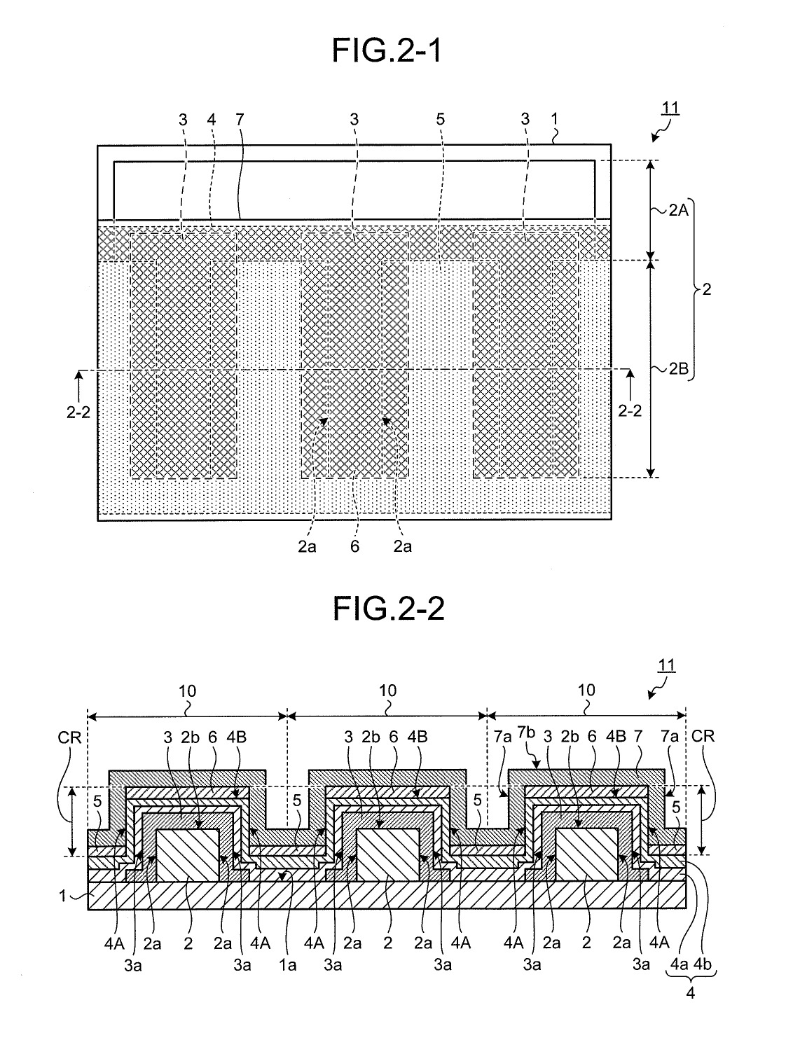

Referring to FIG. 1-1 and FIG. 1-2, the configuration of a thin-film transistor in a first embodiment will be described. FIG. 1-1 is a schematic plan view of the thin-film transistor in the first embodiment. FIG. 1-2 is a schematic sectional view of the thin-film transistor in the first embodiment, illustrating a sectional area cut at the position illustrated by the chain lines 1-2 in FIG. 1-1.

[Substrate]

As illustrated in FIG. 1-1 and FIG. 1-2, a thin-film transistor 10 is generally provided on a substrate 1.

The substrate 1 has a first main surface 1a and a second main surface 1b that are flat surfaces opposed to each other.

Examples of the substrate 1 may include a glass substrate, a silicon substrate, a substrate comprising a metal film, a flexible film substrate formed of a material such as polyethylene terephthalate, polyethylene naphthalate, polyethersulfone, and polyimide, and a plastic substrate. The thickness of the substrate 1 is preferably 10 μm to 5000 μm.

[Protrusion Portion]

The thin-film transistor 10 has a protrusion portion 8. The protrusion portion 8 protrudes from a main surface of the substrate 1, that is, from the first main surface 1a in the thickness direction of the substrate 1 in this configuration example.

The protrusion portion 8 is a structure to serve as a basis for the channel region (described later) to extend in the thickness direction of the substrate 1.

The protrusion portion 8 has a column-shape in this configuration example. In this configuration example, the protrusion portion 8 has a quadrangular prism-shape having a rectangular shape in a section in the direction orthogonal to the longer direction, in which the longer direction corresponds to the direction in which the first main surface 1a extends. The direction that is orthogonal to the longer direction and approximately corresponds to the thickness direction of the substrate 1 is referred to as the shorter direction.

The protrusion portion 8 has a side surface 8a extending in the direction that approximately corresponds to the thickness direction of the substrate 1. The side surface 8a has a rectangular shape in this configuration example, and the shorter direction thereof approximately corresponds to the thickness direction of the substrate 1.

The protrusion portion 8 is formed with an insulating structure 2 provided on the substrate 1 in this configuration example and is provided in contact with the first main surface 1a of the substrate 1.

The protrusion portion 8 is, for example, not limited to the insulating structure 2 described above but may be a convex of convexo concave integrally formed at the substrate 1. In the following description, the entire structure that is in direct contact with the insulating structure 2 or indirectly covers the insulating structure 2 and protrudes from the main surface 1a of the substrate 1 may also be described as the “protrusion portion 8”.

The insulating structure 2 has two side surfaces 2a opposed to each other, each having a rectangular shape, in this configuration example.

The shorter direction of the side surface 2a corresponds to the direction that approximately corresponds to the thickness direction of the substrate 1, and the longer direction thereof is the direction orthogonal to the thickness direction of the substrate 1 and parallel to the first main surface 1a. The top surface 2b of the insulating structure 2 is a surface parallel to the first main surface 1a and is sandwiched between the opposing side surfaces 2a.

The height of the insulating structure 2 in the thickness direction of the substrate 1 (hereinafter referred to as “the height of the insulating structure 2”), that is, the height from the first main surface 1a to the top surface 2b is preferably 10 nm to 2 rim, more preferably 30 nm to 1.5 rim, and further preferably 50 nm to 1 μm. The lower height of the insulating structure 2 is preferable because if so, the length of the channel region in the shorter direction, that is, the channel length is reduced and high on-current and a high cutoff frequency can be obtained.

The angle between the side surface 2a of the insulating structure 2 and the first main surface 1a of the substrate 1 is preferably 60° to 100°, more preferably 80° to 95°, and further preferably 85° to 90°. It is preferable that the angle between the side surface 2a of the insulating structure 2 and the first main surface 1a be closer to 90°, because if so, the channel length is reduced.

As the material of the insulating structure 2, for example, a commercially available photoresist material may be used. Examples of the photoresist material may include “SU-8” and “KMPR” produced by MicroChem Corp.

[Gate Electrode]

A gate electrode 3 covers at least part of the side surfaces 2a of the insulating structure 2 and is in contact with a gate insulating layer 4 described later. In this configuration example, the gate electrode 3 extends across the two opposing side surfaces 2a of the insulating structure 2 so as to cover them. The gate electrode 3 has side surfaces 3a that cover the side surfaces 2a of the insulating structure 2 and extend in the thickness direction of the substrate 1.

Examples of the material of the gate electrode 3 may include metals such as gold, platinum, silver, copper, chromium, palladium, aluminum, indium, molybdenum, and titanium, low-resistance polysilicon, low-resistance amorphous silicon, tin oxide, indium oxide, and indium tin oxide (ITO). These materials may be used singly or in combination of two or more. The gate electrode 3 preferably contains aluminum.

The thickness of the gate electrode 3 is preferably 0.02 μm to 100 μm.

[Gate Insulating Layer]

The gate insulating layer 4 covers the gate electrode 3. In this configuration example, the gate insulating layer 4 covers the gate electrode 3 and the first main surface 1a of the substrate 1 exposed from the gate electrode 3. At least part of the gate electrode 4 is provided in the channel region CR extending along the side surfaces 2a of the insulating structure 2.

Preferably, at least part of the gate electrode 4 is provided in a region extending along the side surface 2a comprising the longest side that is the side of the quadrangular prism extending in the direction orthogonal to the thickness direction of the substrate 1.

The gate insulating layer 4 at least comprises a first layer 4a and a second layer 4b. The first layer 4a is a metal oxide layer, a metal nitride layer, a silicon oxide layer, or a silicon nitride layer. The second layer 4b is a self-assembled monomolecular layer.

In this configuration example, the first layer 4a covers the gate electrode 3 and the first main surface 1a of the substrate 1 exposed from the gate electrode 3, and the second layer 4b covers the first layer 4a. The first layer 4a has side surfaces 4aa that cover the side surfaces 3a of the gate electrode 3 and extend in the thickness direction of the substrate 1. The second layer 4b has side surfaces 4ba that cover the side surfaces 4aa of the first layer 4a and extend in the thickness direction of the substrate 1. The opposing two side surfaces 4ba of the second layer 4b correspond to the side surfaces 4A of the gate insulating layer 4, and the top surface sandwiched between the two side surfaces 4ba corresponds to the top surface 4B of the gate insulating layer 4.

Examples of the metal oxide, the metal nitride, the silicon oxide, and the silicon nitride that constitute first layer 4a may include tantalum oxide, aluminum oxide, aluminum nitride, titanium oxide, yttrium oxide, zirconium oxide, silicon oxide, and silicon nitride. Aluminum oxide, aluminum nitride, silicon oxide, and silicon nitride are preferred as the material of the first layer 4a because they have good insulating properties and a high-density self-assembled monomolecular layer can be formed as the second layer 4b on the surface thereof. Aluminum oxide and silicon oxide are particularly preferred because they can be easily formed at low temperatures by subjecting aluminum or silicon to oxygen plasma treatment or anodic oxidation treatment.

Examples of the material of the self-assembled monomolecular layer as the second layer 4b may include a compound that includes a saturated hydrocarbon group with the number of carbon atoms of 10 or more or a saturated hydrocarbon group with the number of carbon atoms of 10 or more and optionally having a substituent and can be bonded with the first layer 4a.

Specific examples of the material of the second layer 4b may include phosphonic acid derivatives, and silane derivatives having a reactive functional group that can be chemically bonded with a metal oxide, a metal nitride, a silicon oxide, or a silicon nitride. Preferably, the second layer 4b is formed, for example, as a film of a phosphonic acid derivative, a film of a trichlorosilane derivative, or a film of a triethoxysilane derivative.

The phosphonic acid derivative means a compound in which a hydrogen atom bonded with a phosphorus atom comprised in phosphonic acid is substituted with an organic group. The organic groups comprising a monovalent saturated hydrocarbon group and a monovalent saturated hydrocarbon group having a substituent are preferred. A monovalent saturated hydrocarbon group with the number of carbon atoms of 10 or more and a monovalent saturated hydrocarbon group with the number of carbon atoms of 10 or more and having a substituent are more preferred.

The silane derivative means a compound in which at least one hydrogen atom of a silane compound is substituted with an organic group. A monovalent saturated hydrocarbon group and a monovalent saturated hydrocarbon group having a substituent are preferred as the organic group. A monovalent saturated hydrocarbon group with the number of carbon atoms of 10 or more and a monovalent saturated hydrocarbon group with the number of carbon atoms of 10 or more and having a substituent are more preferred.

Examples of the monovalent saturated hydrocarbon group may include an alkyl group with the number of carbon atoms of from 1 to 30, and specific examples may include a methyl group, an ethyl group, a propyl group, a butyl group, a pentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an icosyl group, a heneicosyl group, a docosyl group, a tricosyl group, a tetracosyl group, a pentacosyl group, and a triacontyl group.

Examples of the monovalent saturated hydrocarbon group having a substituent may include an alkyl group with the number of carbon atoms of from 1 to 30 having a substituent. The carbon atom number of the alkyl group does not include the carbon atom number of the substituent.

Examples of the substituent may include a fluorine atom, an aryl group, and an aryloxy group. The aryl group means a group in which one hydrogen atom bonded to an aromatic ring is removed from an aromatic hydrocarbon, and the carbon atom number of the aryl group is generally 6 to 60. Examples of the aryl group may include a phenyl group and a naphthyl group. The carbon atom number of the aryloxy group is generally 6 to 60 and examples thereof may include a phenoxy group.

Examples of the reactive functional group may include a halogen atom and an alkoxy group. The carbon atom number of the alkoxy group as the reactive functional group is generally 1 to 30. Examples of the reactive functional group may include a methoxy group, an ethoxy group, a propoxy group, a butoxy group, a pentyloxy group, a hexyloxy group, a heptyloxy group, an octyloxy group, a nonyloxy group, and a decyloxy group. Examples of the halogen atom as the reactive functional group may include a fluorine atom, a chlorine atom, a bromine atom, and an iodine atom.

Examples of the silane derivative having a reactive functional group may include silane halide derivatives and alkoxysilane derivatives. In terms of forming a densely integrated monomolecular layer of a silane derivative, a trihalogensilane derivative and a trialkoxysilane derivative having three reactive functional groups are preferred, and a trichlorosilane derivative and a trialkoxysilane derivative are more preferred.

Phosphonic acid derivatives are preferred because they can form a densely integrated monomolecular layer in contact with the layer of a metal oxide such as aluminum oxide that is the first layer 4a. In particular, a compound bonded with a monovalent saturated hydrocarbon group with good insulating characteristics, with the number of carbon atoms of 10 or more, such as a long-chain alkyl group with the number of carbon atoms of 10 or more, is preferred as the material of the second layer 4b.

As the phosphonic acid derivative comprising a saturated hydrocarbon group with the number of carbon atoms of 10 or more and the silane derivative comprising a saturated hydrocarbon group with the number of carbon atoms of 10 or more, in terms of forming the second layer 4b in contact with the first layer 4a and having good insulating characteristics, tetradecylphosphonic acid, pentadecylphosphonic acid, hexadecylphosphonic acid, heptadecylphosphonic acid, octadecylphosphonic acid, nonadecylphosphonic acid, decadecylphosphonic acid, tetradecyltrichlorosilane, pentadecyltrichlorosilane, hexadecyltrichlorosilane, heptadecyltrichlorosilane, octadecyltrichlorosilane, nonadecyltrichlorosilane, decadecyltrichlorosilane, tetradecyltriethoxysilane, pentadecyltriethoxysilane, hexadecyltriethoxysilane, heptadecyltriethoxysilane, octadecyltriethoxysilane, nonadecyltriethoxysilane, and decadecyltriethoxysilane are preferred. In terms of enhancing the insulating characteristics, tetradecylphosphonic acid, pentadecylphosphonic acid, hexadecylphosphonic acid, heptadecylphosphonic acid, octadecylphosphonic acid, nonadecylphosphonic acid, and decadecylphosphonic acid are more preferred. The long-chain alkyl group is preferred, because the surface free energy is low and, when an organic semiconductor layer that is the semiconductor layer 7 in contact with the second film 4b is formed, the crystallinity of the organic semiconductor layer is increased, thereby achieving good characteristics.

The monomolecular layer of a compound having a monovalent saturated hydrocarbon group with the number of carbon atoms of 10 or more and having a substituent, in particular, a compound having a group in which the hydrogen atom at the end of a monovalent saturated hydrocarbon group is substituted with an aryl group or an aryloxy group has a high surface free energy and therefore facilitates formation of a layer formed in contact with the monomolecular layer by printing. A phenyl group is preferred as the aryl group, and a phenoxy group is preferred as the aryloxy group. As the phosphonic acid derivative comprising a monovalent saturated hydrocarbon group with the number of carbon atoms of 10 or more and substituted with a phenyl group or a phenoxy group and the silane derivative comprising a monovalent saturated hydrocarbon group with the number of carbon atoms of 10 or more and substituted with a phenyl group or a phenoxy group, phenylethyltrichlorosilane, phenoxytetradecylphosphonic acid, phenoxypentadecylphosphonic acid, phenoxyhexadecylphosphonic acid, phenoxyheptadecylphosphonic acid, phenoxyoctadecylphosphonic acid, phenoxynonadecylphosphonic acid, phenoxydecadecylphosphonic acid, phenoxytetradecyltrichlorosilane, phenoxypentadecyltrichlorosilane, phenoxyhexadecyltrichlorosilane, phenoxyheptadecyltrichlorosilane, phenoxyoctadecyltrichlorosilane, phenoxynonadecyltrichlorosilane, phenoxydecadecyltrichlorosilane, phenoxytetradecyltriethoxysilane, phenoxypentadecyltriethoxysilane, phenoxyhexadecyltriethoxysilane, phenoxyheptadecyltriethoxysilane, phenoxyoctadecyltriethoxysilane, phenoxynonadecyltriethoxysilane, and phenoxydecadecyltriethoxysilane are preferred. Phenoxytetradecylphosphonic acid, phenoxypentadecylphosphonic acid, phenoxyhexadecylphosphonic acid, phenoxyheptadecylphosphonic acid, phenoxyoctadecylphosphonic acid, phenoxynonadecylphosphonic acid, and phenoxydecadecylphosphonic acid are more preferred because good insulating characteristics can be obtained.

A compound having a fluorinated functional group such as pentadecylfluorooctadecylphosphonic acid can also be used as the material of the second layer 4b. These materials may be used singly or in combination of two or more. For example, a mixture of octadecylphosphonic acid and pentadecylfluorooctadecylphosphonic acid can be used. The surface free energy and the threshold voltage of the thin-film transistor can be controlled by changing the ratio of mixing.

The thickness of the gate insulating layer 4, that is, the sum of the thickness of the first layer 4a and the thickness of the second layer 4b in this configuration example, is preferably 50 nm or less, because a thin-film transistor having a channel length of 1 μm or less can suppress the short channel effect and achieve good off characteristics and saturation characteristics. The thickness is preferably 2 nm or more because good insulating characteristics can be achieved. The thickness of the gate insulating layer 4 is preferably 2 nm to 50 nm, more preferably 3 nm to 40 nm, and further preferably 4 nm to 20 nm.

It is particularly preferable that an aluminum oxide layer formed by subjecting an aluminum layer as the gate electrode 3 to plasma treatment be used as the first layer 4a of the gate insulating layer 4 and combined with a self-assembled monomolecular layer of tetradecylphosphonic acid, pentadecylphosphonic acid, hexadecylphosphonic acid, heptadecylphosphonic acid, octadecylphosphonic acid, nonadecylphosphonic acid, decadecylphosphonic acid, or the like, as the second layer 4b provided in contact with the surface of the first layer 4a that is the aluminum oxide layer, because if so, the thickness of the gate insulating layer 4 can be set to about 7 nm to achieve good insulating characteristics.

In order to further enhance insulating characteristics and reduce parasitic capacity, the gate insulating layer 4 may further comprise, in addition to the first layer 4a and the second layer 4b, another functional layer containing an insulating material different from the material of the first layer 4a and the material of the second layer 4b. When the channel length is set to 1 μm or less, the thickness of the gate insulating layer 4 is preferably 50 nm or less, more preferably 40 nm or less, and further preferably 20 nm or less. Another functional layer may be in contact with the first layer 4a or may be in contact with the second layer 4b.

The insulating material used as the material of another functional layer may be an inorganic substance or an organic substance. Examples of the inorganic substance as the material may include silicon oxide, silicon nitride, tantalum oxide, aluminum oxide, aluminum nitride, titanium oxide, yttrium oxide, zirconium oxide, and ferroelectrics such as BaTiO₃ and BiLaTiO. Examples of the organic substance as the material may include a parylene resin, styrene resins, polyimide resins, phenol resins, polyamides, polyurethanes, polycarbonates, polyarylates, polysulfones, epoxy resins, oxetane resins, acrylic resins such as PMMA, polypropylene, polyethylene resins, silicone resins, polyester resins, polyether resins, urea resins, melamine resins, epoxy acrylates, cinnamic acid resins, fluorine-based resins such as PFA, PTFE, PVDF, and CYTOP, vinyl chloride resins, polyvinyl butyral resins, polyester alkyd resins, diallyl phthalate resins, urethane-acrylate resins, proteins such as silk fibroin, and polysaccharides such as cellulose. Organic and inorganic hybrid materials such as polysilsesquioxane may be used. These insulating materials may be used singly or in combination of two or more. These insulating materials may be surface-treated with, for example, a self-assembled monomolecular layer. The surface treatment as described above may improve the insulating characteristics of the insulating film, and may improve the crystallinity of the semiconductor material by changing the surface free energy. Parylene resin is preferred because it can be formed by evaporation and, therefore, the gate insulating layer 4 having a uniform thickness can be easily formed on the side surfaces of a layer derived from the protrusion portion 8.

As described above, because the gate insulating layer 4 is configured with the first layer 4a and the second layer 4b, a thin film having good insulating characteristics and with an extremely small thickness can be formed even in a large-area not-flat region having convexo concave, when compared with conventionally used materials. As a result, the electrical characteristics (in particular, on-current) of the thin-film transistor 10 can be improved.

[Source Electrode and Drain Electrode]

A source electrode 5 and a drain electrode 6 are in contact with the gate insulating layer 4. The source electrode 5 and the drain electrode 6 are provided such that, when viewed from the thickness direction of the substrate 1, at least part of one of the source electrode 5 and the drain electrode 6 overlaps the protrusion portion 8 and the other is provided in the remaining region, and they are electrically isolated from each other.

The arrangement relation between the source electrode 5 and the drain electrode 6 can be reversed by changing, for example, the conductivity type of the semiconductor layer 7.

In this configuration example, the source electrode 5 is provided to cover the top surface 4B of the gate insulating layer 4 so as to overlap the insulating structure 2 that is the protrusion portion 8 when viewed from the thickness direction of the substrate 1. The drain electrode 6 is provided in the remaining region that is the region one level lower than the protrusion portion 8, that is, the top surface 4B in the thickness direction of the substrate 1 (hereinafter also referred to as the flat region). That is, the source electrode 5 and the drain electrode 6 are spaced apart from each other in the thickness direction of the substrate 1 and electrically isolated from each other.

The source electrode 5 and the drain electrode 6 are preferably formed of a material with low resistance. As the material with low resistance, gold, platinum, silver, copper, chromium, palladium, aluminum, indium, molybdenum, titanium, calcium, lithium fluoride, and barium are preferred. These materials may be used singly or in combination of two or more.

The thickness of each of the source electrode 5 and the drain electrode 6 is preferably 0.005 μm to 1000 μm.

The semiconductor layer 7 is in contact with at least part of the source electrode 5, at least part of the drain electrode 6, and at least part of the gate insulating layer 4 in the channel region CR directly or with a functional layer interposed.

The semiconductor layer 7 covers the source electrode 5 and the drain electrode 6 as well as the gate insulating layer 4 exposed from the source electrode 5 and the drain electrode 6 in this configuration example. The semiconductor layer 7 has side surfaces 7a that cover the side surfaces 4ba of the second layer 4b and extend in the thickness direction of the substrate 1.

A region of the semiconductor layer 7 that extends along the side surface 2a of the insulating structure 2, that is, the region that extends in the thickness direction of the substrate 1 and is sandwiched between the region in contact with the source electrode 5 and the region in contact with the drain electrode 6 is the channel region CR serving as the channel of the thin-film transistor 10.

In the thin-film transistor 10, a functional layer may be interposed between the source electrode 5 and the drain electrode 6, and the semiconductor layer 7. A functional layer may be interposed between the gate insulating layer 4 and the semiconductor layer 7. Preferably, a semiconductor material different from the semiconductor material contained in the semiconductor layer 7 is used as the material contained in such a functional layer. Interposing such a functional layer may reduce the contact resistance between the source electrode 5 and the drain electrode 6, and the semiconductor layer 7 and further enhance the characteristics such as on-current and a cutoff frequency of the thin-film transistor 10.

Examples of the functional layer may include layers of a low molecular compound having electron transportability and hole transportability, alkaline metals, alkaline-earth metals, rare-earth metals, complexes of these metals and organic compounds, alkylthiol compounds, aromatic thiol compounds, and aromatic thiol compounds such as fluorinated alkylaromatic thiol compounds.

The semiconductor material that can be used for the semiconductor layer 7 may be an inorganic semiconductor material or an organic semiconductor material.

Examples of the inorganic semiconductor material may include silicon semiconductor materials such as amorphous silicon, polysilicon, microcrystalline silicon, and monocrystalline silicon, germanium, compound semiconductor materials such as CdS, PbTe, PbSnTe, GaP, GaAlAs, GaAs, GaN, InP, and InGaAs, and oxide semiconductor materials such as InGaZnO, ZnO, In₂O₃, ZnSnO, InZnO, InSnO, InMgO, AlZnSnO, InHfZnO, InSnZnO, GaZnO, and InGaO. Polysilicon, microcrystalline silicon, GaAs, InGaAs, GaN, InGaZnO, InSnZnO, GaZnO, and InGaO are preferred as the inorganic semiconductor material because high charge-carrier mobility can be obtained. In terms of improving productivity, amorphous silicon, InGaZnO, InSnZnO, GaZnO, and InGaO are preferred as the inorganic semiconductor material.

Some of silicon semiconductor materials and oxide semiconductor materials can be formed by applying or printing precursors of semiconductor materials. It is preferable to form the semiconductor layer 7 by coating or printing using such materials because if so, the thin-film transistor 10 can be manufactured at lower costs. Those inorganic semiconductor materials may be used singly or in combination of two or more.

The organic semiconductor material may be a low molecular compound or a macromolecular compound. Examples of the organic semiconductor material as a low molecular compound may include tetracene, pentacene, rubrene, benzothienobenzothiophene, dinaphthothienothiophene, naphthodithiophene, anthradithiophene, perixanthenoxanthene, and derivatives of these compounds. Derivatives in which a hydrogen atom of these compounds is substituted with a substituent such as an alkyl group or an alkoxy group are preferred because the solubility to an organic solvent is improved. In terms of having high charge-carrier mobility, 6,13-bistriisopropylsilylethynylpentacene, 1,4,8,11-tetramethyl-6,13-triethylsilylethynylpentacene, 2,7-dioctyl[1]benzothieno[3,2-b][1]benzothiophene, 2,9-octyl-dinaphtho[2,3-b:2′,3′-f]thieno[3,2-b]thiophene, 2,8-difluoro-5,11-bis(triethylsilylethynyl)anthradithiophene are preferred. Examples of the organic semiconductor as a macromolecular compound may include compounds having, as a constitutional unit or a repeating unit, a group obtained by removing two hydrogen atoms from thiophene, thiazole, thienothiophene, thiadiazole, benzodithiophene, naphthodithiophene, anthradithiophene, benzobisthiazole, benzothiadiazole, naphthalenebisthiadiazole, fluorene, cyclopentadithiophene, triphenylamine, diketopyrrolopyrrole, indacenodithiophene, and derivatives thereof. Specific examples may include poly(3-hexylthiophene), poly(9,9-dioctylfluorene-co-bithiophene), and compounds of Formulae (1) to (9) below. These organic semiconductor materials may be used singly or in combination of two or more.

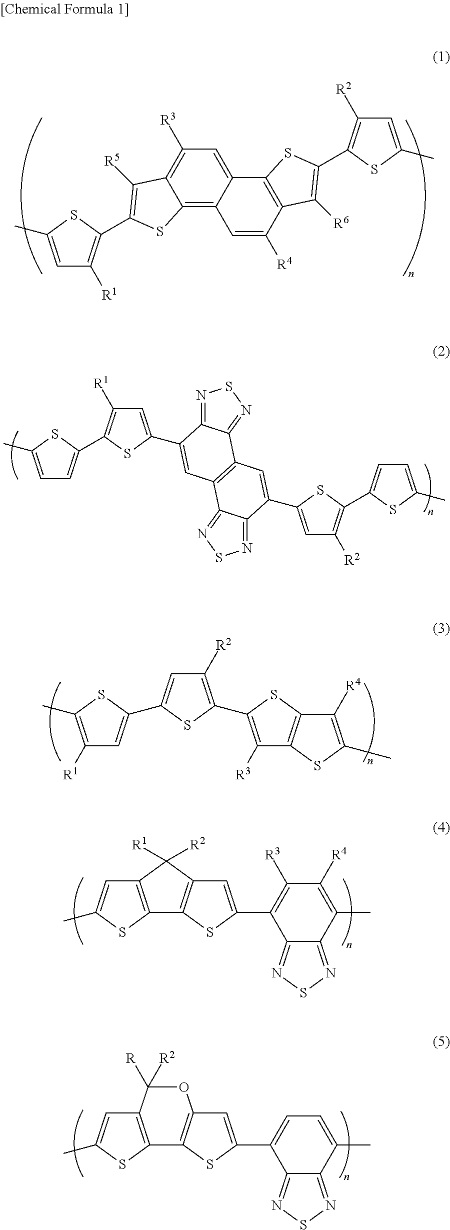

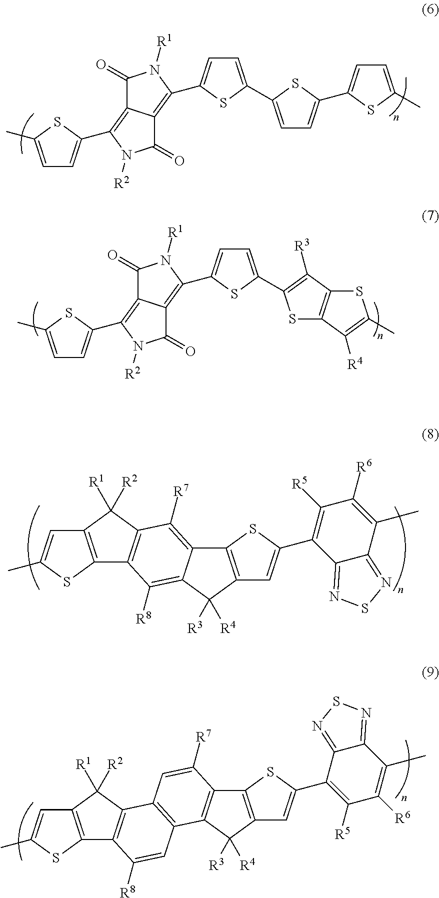

In Formulae (1) to (9), R¹, R², R³, R⁴, R⁵, R⁶, R⁷, and R⁸ are each independently a hydrogen atom, an alkynyl group, an alkenyl group, an alkyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, an amino group, a substituted amino group, a silyl group, a substituted silyl group, a halogen atom, a heterocyclic group, or a cyano group. These groups may further have a substituent.

In Formulae (1) to (9), n is an integer of from 1 or more. The range of n is preferably a range in which the polystyrene-equivalent average number molecular weight is 3000 or more, more preferably 5000 to 1000000, and further preferably 10000 to 500000.

The alkynyl group is generally a group with the number of carbon atoms of from 2 to 30 and examples thereof may include an ethinyl group. The alkenyl group is generally a group with the number of carbon atoms of from 2 to 30 and examples thereof may include a vinyl group. The alkyl group is generally a group with the number of carbon atoms of from 1 to 30 and examples thereof may include a methyl group, an ethyl group, a propyl group, a butyl group, a hexyl group, and an octyl group. The alkoxy group is generally a group with the number of carbon atoms of from 1 to 30 and examples thereof may include a methoxy group, an ethoxy group, a propoxy group, and a butoxy group. The alkylthio group is generally a group with the number of carbon atoms of from 1 to 30 and examples thereof may include a methylthio group. The aryl group means a group in which one hydrogen atom bonded to an aromatic ring is removed from an aromatic hydrocarbon, and the aryl group is generally a group with the number of carbon atoms of from 6 to 60. Examples of the aryl group may include a phenyl group and a naphthyl group. The aryloxy group is generally a group with the number of carbon atoms of from 6 to 60 and examples thereof may include a phenoxy group. The arylthio group is generally a group with the number of carbon atoms of from 6 to 60 and examples thereof may include a phenylthio group. The arylalkyl group is generally a group with the number of carbon atoms of from 7 to 60 and examples thereof may include a phenylmethyl group. The arylalkoxy group is generally a group with the number of carbon atoms of from 7 to 60 and examples thereof may include a phenylmethoxy group. The arylalkylthio group is generally a group with the number of carbon atoms of from 7 to 60 and examples thereof may include a phenylmethylthio group. The arylalkenyl group is generally a group with the number of carbon atoms of from 8 to 60 and examples thereof may include a styryl group. The arylalkynyl group is generally a group with the number of carbon atoms of from 8 to 60 and examples thereof may include a phenylacetylenyl group. The substituted amino group refers to a group in which one or two hydrogen atoms in an amino group are substituted with substituents, and examples of the substituent may include an alkyl group and an aryl group. The substituted silyl group refers to a group in which one, two, or three hydrogen atoms in a silyl group are substituted with substituents. Generally, all of three hydrogen atoms in a silyl group are substituted with substituents, and examples of the substituents may include alkyl groups and aryl groups. Examples of the halogen atom may include a fluorine atom, a chlorine atom, a bromine atom, and an iodine atom. The heterocyclic group means a group in which one hydrogen atom is removed from a heterocyclic compound.

Examples of the substituent that the groups above optionally have may include a halogen atom.

The end structure of the macromolecular compound used as the organic semiconductor material is preferably a chemically stable structure in terms of the characteristics and durability of the thin-film transistor 10 when used for the semiconductor layer 7 of the thin-film transistor 10. When the polymer described above has a highly reactive end group, it is preferable to substitute the highly reactive end group with a chemically stable end group or protect the end of the polymer with a protecting group.

Examples of the chemically stable end group may include an aryl group and a heteroaryl group.

Nanomaterials such as carbon nanotube, graphene, C60 fullerene, and derivatives thereof may be used as the material of the semiconductor layer 7. These materials may be used singly or in combination of two or more.

A solvent used during production or other components inevitably mixed may be included in the semiconductor layer 7. In terms of having good carrier transportability and in terms of easily forming a thin film with sufficient strength, the thickness of the semiconductor layer 7 is preferably 1 nm to 2 rim, further preferably 5 nm to 500 nm, and particularly preferably 20 nm to 200 nm.

Although the channel region CR functioning as the channel may be provided only one side surface 2a side of the opposing two side surfaces 2a of the insulating structure 2, it is preferably provided on both side surface 2a sides because even higher on-current can be obtained. Mainly in terms of reducing parasitic capacity, the channel region CR may be provided only on one side surface 2a side of the insulating structure 2.

When the channel region CR is provided only on one side surface 2a side of the insulating structure 2, if the semiconductor layer 7 is provided on the side surface that is not in contact with the gate electrode 3 and where the channel is not to be formed, current may flow between the source electrode 5 and the drain electrode 6 even when the thin-film transistor 10 is in off state. It is therefore preferable to provide the semiconductor layer 7 only on the side surface 2a side where the channel is to be formed.

The method for manufacturing the thin-film transistor 10 will be described later.

### Second Embodiment

### Configuration Example of Integrated Thin-Film Transistor

Referring to FIG. 2-1 and FIG. 2-2, the configuration of a thin-film transistor (integrated thin-film transistor) in a second embodiment will be described. FIG. 2-1 is a schematic plan view of the thin-film transistor in the second embodiment. FIG. 2-2 is a schematic sectional view of the thin-film transistor in the second embodiment cut at the position illustrated by the chain lines 2-2 in FIG. 2-1.

The second embodiment relates to an integrated thin-film transistor 11 in which a plurality of thin-film transistors 10 in the first embodiment previously described are arranged on the substrate 1, the gate electrodes 3, the source electrodes 5, and the drain electrodes 6 of the arranged thin-film transistors 10 are electrically connected to each other, and the thin-film transistors 10 operate integrally as a single transistor.

The materials and arrangement relation of the layers are basically the same as in the first embodiment previously described. A detailed description of the same issues is omitted, and only the differences are described.

As illustrated in FIG. 2-1 and FIG. 2-2, the integrated thin-film transistor 11 comprises three thin-film transistors 10. These three thin-film transistors 10 are arranged at regular intervals.

In this configuration example, the insulating structure 2 is provided on the first main surface 1a of the substrate 1. As illustrated in FIG. 2-1, the insulating structure 2 has a comb-shape as a whole. The insulating structure 2 has a rectangular parallelepiped-shape base portion 2A and comb tooth portions 2B protruding from the base portion 2A. The insulating structure 2 has three comb tooth portions 2B spaced apart from each other at regular intervals from the base portion 2A and extending parallel to each other.

The width of each of the comb tooth portions 2B, that is, the width in the direction orthogonal to the direction in which the comb tooth portions 2B extend and the gap between the adjacent comb tooth portions 2B, is preferably 1 μm to 20 rim, and further preferably 2 μm to 10 rim, because if the width of the comb tooth portion 2B and the gap between the adjacent comb tooth portions 2B are too narrow, the resistance of the electrode provided above or in the lateral direction of the insulating structure 2, that is, on the side surface side may increase, and if the gap between the adjacent comb tooth portions 2B is wide, the integration is difficult and a high current value may be unobtainable. The width of the comb tooth portion 2B and the gap between the adjacent comb tooth portions 2B may be equal or may be different. When the semiconductor layer 7 is formed by a coating method or a printing method, if the gap between the adjacent comb tooth portions 2B is narrow, the applied semiconductor material (ink) may be accumulated between the comb tooth portions 2A, leading to lowering of characteristics, such as increase in off-current and leakage current. Such a case may be solved by increasing the gap between the adjacent comb tooth portions 2B. In this case, the degree of integration can be maintained by reducing the width of the comb tooth portion 2B.

In this configuration example, the gate electrodes 3 are provided on three comb tooth portions 2B so as to cover the comb tooth portions 2B individually and are configured integrally on the first main surface 1a of the substrate 1 and/or the base portion 2A of the insulating structure 2 to be electrically connected with each other. The gate electrode 3 may be configured to integrally extend across all of the three comb tooth portions 2B.

In this configuration example, the gate insulating layer 4 is provided to integrally extend across part of the base portion 2A and all of the three comb tooth portions 2B of the insulating structure 2.

In this configuration example, the drain electrodes 6 are provided to cover part of the insulating structure 2 and only the comb tooth portion 2B covered with the gate insulating layer 4 (only the top surface 4B of the gate insulating layer 4). That is, the drain electrodes 6 provided on three comb tooth portions 2B are electrically connected with each other on the base portion 2A of the insulating structure 2.

The source electrode 5 is formed in a region not overlapped with the protrusion portion 8 or the drain electrode 6, when viewed from the thickness direction of the substrate, where the insulating structure 2 and the drain electrode 6 are not formed, that is, only in the flat region. The source electrode 5 is isolated from the drain electrode 6 in the thickness direction of the substrate 1. The source electrodes 5 are integrally configured to assemble in the flat region on the tip end side of the comb tooth portions 2B positioned on the opposite side to the base portion 2A, and operate also in an electrically integrated manner.

In this configuration example, the semiconductor layer 7 is provided to integrally extend across part of the base portion 2A and all of the three comb tooth portions 2B of the insulating structure 2.

As described above, it is more preferable to integrate a plurality of thin-film transistors 10 on the substrate 1 and electrically connect the gate electrodes 3, the source electrodes 5, and the drain electrodes 6 formed on a basis of the comb tooth portions 2B to operate the thin-film transistors 10 as a single transistor, because even higher on-current can be obtained.

(Method for manufacturing Thin-Film Transistor and Integrated Thin film Transistor)

Referring to FIG. 1-1 to FIG. 2-2, a method for manufacturing the thin-film transistor in the first embodiment and the integrated thin-film transistor in the second embodiment will be described.

[Step of Preparing Substrate]

First of all, the substrate 1 having the configuration as previously described is prepared. When the protrusion portions 8 are formed in the substrate 1 per se, the protrusion portions 8 may be formed by processing the substrate 1 by a patterning step comprising a nanoimprinting method and an etching step. Alternatively, a silicon substrate or other substrates can be used as the substrate 1, protrusion portions 8 may be formed by a conventionally known mask pattern forming step and a dry etching step using a mask pattern, and the surfaces of the protrusion portions 8 are oxidized, if necessary, by heating or other treatment to impart insulating characteristics to serve as a substitute for the insulating structure 2.

[Step of Forming Insulating Structure]

In this configuration example, the insulating structure 2 is formed on the main surface 1a of the substrate 1. The insulating structure 2 can be formed, for example, by photolithography in which after a photoresist material is applied on the first main surface 1a of the substrate 1 by a method such as spin coating method, a development step, an exposure step, and a cleaning step are successively performed under the conditions depending on the selected photoresist material. The height of the insulating structure 2 can be adjusted by controlling, for example, the concentration of the photoresist material and the rotation speed in spin coating method.

The insulating structure 2 can be formed by a nanoimprinting method in which a layer of the material of the insulating structure 2 is formed and pressed against a mold configured to form a desired shape of the insulating structure 2 to be patterned.

Examples of the nanoimprinting method may include thermal nanoimprinting method and photo nanoimprinting method.

In thermal nanoimprinting method, the insulating structure 2 can be formed using an insulating material and a thermoplastic resin such as a polymethyl methacrylate resin. Photo nanoimprinting method is preferred because it does not require treatment at high temperatures and therefore enables the insulative protrusion portion 8 to be formed even on an inexpensive plastic substrate of polyethylene terephthalate or the like, and the time required for curing is short, resulting in high productivity.

[Step of Forming Gate Electrode]

Next, the gate electrode 3 is formed. The gate electrode 3 can be formed in contact with at least part of the side surfaces 2a and the top surface 2b of the insulating structure 2 in this configuration example, by depositing a material of the gate electrode 3 from the diagonal direction relative to the first main surface 1a of the substrate 1 by vacuum evaporation method or sputtering method. When the gate electrode 3 is formed on a plurality of opposing side surfaces 2a, the material is deposited from one side surface 2a side, and a film formation step is thereafter performed from the other side surface 2a side with the angle changed. These steps are repeated, if necessary. Alternatively, when a film formation step is carried out by vacuum evaporation method or sputtering method, the gate electrode 3 can be formed on a plurality of side surface 2a sides in a single step by forming a film while rotating the substrate 1 provided with the insulating structure 2. If the surface free energy is increased only at the side surfaces 2a of the insulating structure 2 using the previously described self-assembled monomolecular layer or a commercially available, conventionally known surface-treating agent, the gate electrode 3 can be formed on at least part of the side surface 2a side of the insulating structure 2 in a self-alignment manner by subsequently applying metal ink and performing heating treatment. Alternatively, the gate electrode 3 can be formed on the side surfaces 2a by a printing method in which metal ink is applied on a flexible mold made of, for example, a silicone resin such as polydimethylsiloxane, and the applied metal ink on the mold is transferred onto the side surfaces 2a.

When the insulating structure 2 having a plurality of comb tooth portions 2B is provided on the substrate 1 as illustrated in FIG. 2-1 and FIG. 2-2, excessive deposition of the material of the gate electrode 3 on the substrate 1 may be prevented and the parasitic capacity may be reduced by appropriately adjusting the angle of depositing the material of the gate electrode 3, because the region sandwiched between the adjacent comb tooth portions 2B, which is the lower region close to the substrate 1, that is, the flat region is hidden by the insulating structure 2 as viewed from the supply source of the raw material. The deposition of the material of the gate electrode 3 in the unnecessary region can be prevented by photolithography. Specifically, after the material of the gate electrode 3 is deposited on the entire exposed surface, a pattern of a photoresist is formed so as to cover only the region where the material of the gate electrode 3 is deposited and the gate electrode 3 is to be formed. After the material of the gate electrode 3 is etched away in the unnecessary region, that is, the region exposed from the pattern of the photoresist, the pattern of the photoresist is removed, whereby the material of the gate electrode 3 can be deposited only in the necessary area. Alternatively, the gate electrode 3 can be formed only in an appropriate region by a lift-off step in which a pattern of a photoresist is formed in advance only in a region where the material of the gate electrode 3 is not intended to be deposited, and the material of the gate electrode 3 is thereafter deposited on the entire surface of the substrate, followed by removing the pattern of the photoresist.

The gate electrode 3 preferably contains a metal that is easily oxidized or nitrified or silicon when an oxide film or a nitride film obtained by subjecting a metal layer or a silicon layer that constitutes the gate electrode 3 (or the silicon substrate) to plasma treatment or heating treatment is used as the gate insulating layer 4, that is, the first layer 4a. Aluminum and silicon are more preferred as the material of the gate electrode 3 because layers of aluminum oxide and silicon oxide having good insulating characteristics can be formed on the surface thereof by plasma treatment. Aluminum is particularly preferred as the material of the gate electrode 3 because an aluminum oxide layer having high insulating characteristics can be formed on the surface thereof.

[Step of Forming Gate Insulating Layer]

Next, the gate insulating layer 4 is formed. In this configuration example, the gate insulating layer 4 is formed on the substrate 1 provided with the insulating structure 2 and the gate electrode 3.

First, the first layer 4a comprised in the gate insulating layer 4 is formed. Examples of the method for forming the first layer 4a may include vacuum evaporation method, sputtering method, pulsed laser deposition method, atomic layer deposition method, organometallic chemical vapor deposition method, molecular beam epitaxy method, electron beam evaporation method, chemical vapor deposition method, anodic oxidation method, thermal oxidation method, and plasma treatment method. Vacuum evaporation method, sputtering method, anodic oxidation method, and plasma treatment method (plasma oxidation method) are preferred as the method for forming the first layer 4a because the first layer 4a can be formed at once over a large area at low costs. When the material of the first layer 4a is a compound soluble in a liquid such as an organic solvent, the first layer 4a can be formed by a coating method or a printing method. Examples of the coating method and the printing method may include spin coating method, casting method, microgravure coating method, gravure coating method, bar coating method, roll coating method, wire bar coating method, dip coating method, spray coating method, screen printing method, flexographic printing method, offset printing method, inkjet printing method, dispenser printing method, nozzle coating method, capillary coating method, microcontact printing method, and a combination of those methods. An example of the combination of those methods is gravure/offset printing method which is a combination of gravure coating method and offset printing method. With such coating methods and printing methods, a device having a larger area can be produced easily. Among the coating methods and the printing methods, spin coating method, inkjet printing method, flexographic printing method, screen printing method, microcontact printing method, gravure coating method, offset printing method, and gravure/offset printing method are preferred.

As a method for forming the first layer 4a, a metal layer or a silicon layer (silicon substrate) that constitutes the gate electrode 3 may be subjected to plasma treatment, anodic oxidation treatment, or heating treatment to form an oxide film or a nitride film. If the first layer 4a is formed in this manner, the first layer 4a that covers the gate electrode 3 can be formed in a self-alignment manner.

In plasma treatment, if discharge output power is too high, the flatness of the surfaces of the gate electrode 3, the substrate 1, and the like may be impaired, so that the insulating characteristics and the field effect mobility of the first layer 4a may be lowered. If discharge output power is too low, the gate electrode 3 may be treated insufficiently, so that the first layer 4a having a thickness enough to achieve good insulating characteristics may be unobtainable. Therefore, the discharge output power in plasma treatment is preferably 50 W to 500 W, more preferably 100 W to 450 W, particularly preferably 150 W to 400 W.

Next, the second layer 4b is formed so as to cover the first layer 4a. The second layer 4b that is a self-assembled monomolecular layer can be formed by dissolving or dispersing a compound that can be bonded to the compound contained in the first layer 4a as previously described in an organic solvent or other substances and dipping the substrate 1 with the first layer 4a formed thereon. Alternatively, the second layer 4b can be formed by a vapor process or may be formed by the same method as the coating method and the printing method used in the step of forming the first layer 4a described above. Because those methods allow formation at relatively low temperatures, an inexpensive plastic substrate with low heat resistance can be used as the substrate 1.

When a self-assembled monomolecular layer is selectively formed only on the surface of the first layer 4a, the first layer 4a may be patterned by a patterning method including photolithography method or a method such as a printing method. When a self-assembled monomolecular layer is selectively formed only on the surface of the first layer 4a and the first layer 4a is selectively formed only on the surface of the gate electrode 3, the gate electrode 3 may be patterned by a patterning method including photolithography method and a method such as a printing method.

[Step of Forming Source Electrode and Drain Electrode]

Next, the source electrode 5 and the drain electrode 6 are formed. The source electrode 5 and the drain electrode 6 can be formed by depositing the materials of the source electrode 5 and the drain electrode 6 onto the substrate 1 from above on the first main surface 1a side of the substrate 1. Examples of the method for forming the source electrode 5 and the drain electrode 6 may include vapor deposition method and sputtering method as described above.

If the material is deposited on the entire exposed surface from above on the first main surface 1a side of the substrate 1, in this configuration example, the source electrode 5 is formed on the top surface 4B of the gate insulating layer 4 immediately above the protrusion portion 8, and the drain electrode 6 is formed in the remaining region on the gate insulating layer 4 in the flat region outside the protrusion portion 8. On the side surfaces 4A of the gate insulating layer 4, the materials of the source electrode 5 and the drain electrode 6 do not adhere, and the side surfaces 4A are left exposed, so that the source electrode 5 and the drain electrode 6 are isolated from each other in the thickness direction of the substrate 1 and electrically isolated from each other.

It is preferable to form the source electrode 5 and the drain electrode 6 as described above, because the source electrode 5 and the drain electrode 6 can be formed collectively in the region immediately above the insulating structure 2 and in the flat region outside the insulating structure 2 (protrusion portion 8) in a single deposition step. If the surface free energy at the top surface 2b of the insulating structure 2 or the top surface of the exposed predetermined layer is increased compared with the side surfaces 2a of the insulating structure 2 or the side surfaces of the exposed predetermined layer, using a self-assembled monomolecular layer or a surface treating agent, the source electrode 5 and the drain electrode 6 can be formed collectively in a self-alignment manner by applying metal ink only in the region where the surface free energy is increased, and performing heating treatment. Deposition of the materials of the source electrode 5 and the drain electrode 6 in an unnecessary region can be prevented by photolithography method. The materials of the source electrode 5 and the drain electrode 6 may be deposited only in the necessary region by using a mask pattern that covers the region where the materials of the source electrode 5 and the drain electrode 6 are not intended to be deposited, when the materials of the source electrode 5 and the drain electrode 6 are deposited. The source electrode 5 and the drain electrode 6 can be formed only in the appropriate position also by a printing method. Specifically, the source electrode 5 and the drain electrode 6 can be formed collectively in the region immediately above the insulating structure 2 and in the flat region outside the insulating structure 2 (protrusion portion 8) without the materials of the source electrode 5 and the drain electrode 6 adhering to the side surfaces 4A of the gate insulating layer 4, by a printing method in which metal ink is applied on a flexible mold made of, for example, a silicone resin such as polydimethylsiloxane and the applied metal ink on the mold is transferred.

[Step of Forming Semiconductor Layer]

Next, the semiconductor layer 7 is formed. In this configuration example, the semiconductor layer 7 is formed so as to cover the source electrode 5 and the drain electrode 6 as well as the gate insulating layer 4 exposed from the source electrode 5 and the drain electrode 6.

Examples of the method for forming the semiconductor layer 7 included in the thin-film transistor 10 and the integrated thin-film transistor 11 in the present invention may include vacuum evaporation method, sputtering method, pulsed laser deposition method, atomic layer deposition method, organometallic chemical vapor deposition method, plasma chemical vapor deposition method, solid phase crystallization method, epitaxial growth method, molecular beam epitaxy method, electron beam evaporation method, vapor phase growth method, the sol-gel method, chemical bath deposition method, coating methods, and printing methods. Vacuum evaporation method, sputtering method, plasma chemical vapor deposition method, the sol-gel method, coating methods, and printing methods are preferred as the method for forming the semiconductor layer 7, because the layer can be formed over a large area inexpensively.

The same methods as in the method for forming the gate insulating layer 4 previously described may be used as the coating methods and the printing methods that may be used for forming the semiconductor layer 7. If the coating methods and the printing methods are used, a thin film having high carrier transportability can be obtained and, in addition, a large-area device can be formed easily.

As the coating methods and the printing methods that may be used for forming the semiconductor layer 7, spin coating method, inkjet printing method, flexographic printing method, screen printing method, microcontact printing method, gravure coating method, offset printing method, and gravure/offset printing method are preferred.

Liquid (ink) that may be used in the coating methods and the printing methods can be prepared, for example, by a method in which a compound that is a material for forming the semiconductor layer 7 or a precursor thereof is dissolved in a solvent or by a method in which it is dispersed in a dispersion medium. Any solvent or dispersion medium may be used as long as the solvent can well dissolve or disperse the compound or the precursor used. Examples of the solvent or the dispersion medium may include unsaturated hydrocarbon solvents such as toluene, xylene, mesitylene, tetralin, decalin, bicyclohexyl, butylbenzene, sec-butylbenzene, and tert-butylbenzene, saturated hydrocarbon halide solvents such as carbon tetrachloride, chloroform, dichloromethane, dichloroethane, chlorobutane, bromobutane, chloropentane, bromopentane, chlorohexane, bromohexane, chlorocyclohexane, and bromocyclohexane, unsaturated hydrocarbon halide solvents such as chlorobenzene, dichlorobenzene, and trichlorobenzene, and ether solvents such as tetrahydrofuran and tetrahydropyran. The content of the component excluding the solvent or dispersion medium in the liquid is preferably 0.1% by mass to 5% by mass because a thin film can be formed favorably. If dissolution or dispersion of the compound used is insufficient, heating treatment as described later may be carried out.

In forming the semiconductor layer 7, the semiconductor layer 7 can be formed by coating or printing the substrate 1 having predetermined components formed thereon with the liquid. When the liquid contains a solvent or a dispersion medium, the solvent or the dispersion medium is preferably removed simultaneously with coating or printing or after coating or printing.

Such coating or printing may be performed with the liquid in a heated state. By performing coating or printing with liquid in a heated state, a liquid with a higher concentration can be applied or printed, so that a more uniform thin film can be formed. In addition, for example, a material that is difficult to apply at room temperature can be selected and used. Coating or printing in a heated state can be performed, for example, using a pre-heated liquid or by applying or printing a liquid while heating the substrate.

In an organic thin-film transistor having the semiconductor layer 7 of an organic compound, the step of imparting a predetermined orientation may be further performed to the formed organic semiconductor layer because the carrier transportability in the organic semiconductor layer can be enhanced. In the organic semiconductor layer subjected to the step of imparting a predetermined orientation, the carrier transportability tends to be further enhanced because the molecules that constitute the organic semiconductor layer are aligned in one direction.

As a method for imparting a predetermined orientation to the organic semiconductor layer, for example, a conventionally known alignment method known as a method for aligning liquid crystal molecules can be used. As the alignment method, rubbing, optical alignment, sharing (shear stress applying method), and a coating method for controlling the dry direction such as lift coating are simple and easily applied. In particular, rubbing and sharing are preferred.

When a semiconductor material that constitutes the semiconductor layer 7 is applied or printed on the self-assembled monomolecular layer that is the second layer 4b, it may be preferable to pattern the self-assembled monomolecular layer because the semiconductor layer 7 can be easily formed at a predetermined position. The self-assembled monomolecular layer can be patterned by selectively applying a solution containing a compound for forming a desired self-assembled monomolecular layer by a printing method. Alternatively, the self-assembled monomolecular layer can be patterned by forming a self-assembled monomolecular layer all over the surface of the insulating film and thereafter applying ultraviolet light or laser light to an unnecessary area to selectively remove the self-assembled monomolecular layer. In forming the semiconductor layer 7, another self-assembled monomolecular layer may be further formed at the area where the self-assembled monomolecular layer is removed.

Through the steps as described above, the thin-film transistor 10 in the first embodiment and the integrated thin-film transistor 11 in the second embodiment are manufactured.

It is preferable to additionally form a protective film that covers and seals the thin-film transistor in order to protect the thin-film transistor, after manufacturing the thin-film transistor. The protective film can shield the thin-film transistor from the air and suppress degradation of the characteristics of the thin-film transistor. In addition, the protective film can reduce influences that may occur when a display device to drive is further formed on the thin-film transistor.

Examples of the method for forming the protective film may include a method for covering the thin-film transistor with a UV-setting resin film, a thermosetting resin film, an SiONx film as an inorganic material, or other films. For effective shielding from the air, the steps before formation of the protective film after manufacturing the thin-film transistor are preferably performed without exposure to the air (for example, in a dry nitrogen gas atmosphere or in a vacuum).

### Third Embodiment

A configuration example of a thin-film transistor in a third embodiment will be described. In the following description of the embodiments, the figures illustrating the “thin-film transistor” corresponding to FIG. 1-1 and FIG. 1-2 and the plan view corresponding to FIG. 2-1 are omitted. The following embodiments, however, include not only the “integrated thin-film transistor” illustrated in the figures but also the “thin-film transistor” as described above with reference to FIG. 1-1 and FIG. 1-2. In the following description of the embodiments, a detailed description of the same components and the same manufacturing steps as in the first embodiment and the second embodiment previously described may be omitted.

(Configuration Example of Thin-Film Transistor)

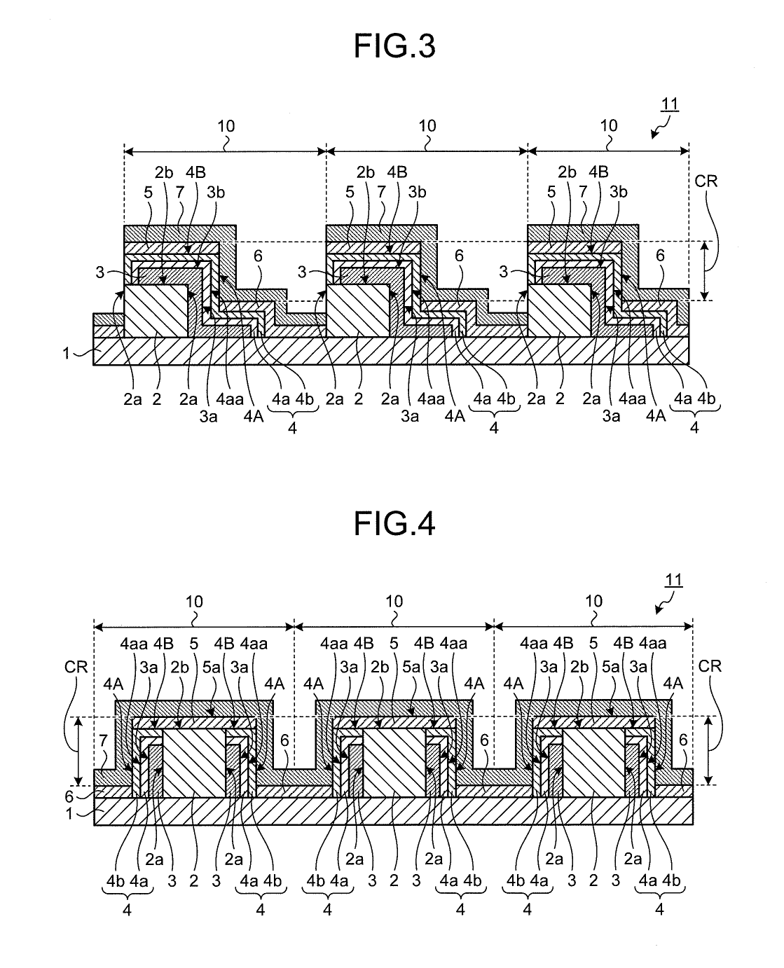

Referring to FIG. 3, the configuration of the thin-film transistor (integrated thin-film transistor) in the third embodiment will be described. FIG. 3 is a schematic sectional view illustrating the thin-film transistor in the third embodiment in the same manner as in FIG. 2-2.

The thin-film transistor 10 and the integrated thin-film transistor 11 in the third embodiment have the channel region CR only one side of the opposing two side surfaces 2a of the insulating structure 2.

In the third embodiment, the protrusion portion 8 is the insulating structure 2 provided on the substrate 1, the gate electrode 3 covers at least part of the side surfaces 2a of the insulating structure 2, the gate insulating layer 4 covers the gate electrode 3, the source electrode 5 and the drain electrode 6 are in contact with the gate insulating layer 4, and the semiconductor layer 7 covers the source electrode 5 and the drain electrode 6 as well as the gate insulating layer 4.

A configuration example of the third embodiment will be described more specifically. In this configuration example, three thin-film transistors 10 are provided on the substrate 1. The insulating structure 2 is provided on the first main surface 1a.

The gate electrode 3 is provided only one side of the opposing two side surfaces 2a of the insulating structure 2. The gate electrode 3 is provided to cover surfaces from the first main surface 1a exposed from the side surfaces 2a of the insulating structure 2 along the side surface 2a on one side of the insulating structure 2, and reach the top surface 2b to cover part of the top surface 2b.

The first layer 4a of the gate insulating layer 4 covers the gate electrode 3 and is provided to cover surfaces from the first main surface 1a exposed from the gate electrode 3 along the side surface 3a of the gate electrode 3, cover the top surface 3b, and reach the exposed top surface 2b of the insulating structure 2. The second layer 4b covers the first layer 4a and is provided to cover surfaces from the first main surface 1a exposed from the first layer 4a along the side surface 4aa of the first layer 4a, and cover the exposed top surface 2b of the insulating structure 2.

The source electrode 5 and the drain electrode 6 are in contact with the gate insulating layer 4, that is, the second layer 4b. The source electrode 5 covers the top surface 4B of the gate insulating layer 4. The drain electrode 6 is provided in the flat region outside the top surface 4B where the source electrode 5 is not provided when viewed from the thickness direction of the substrate 1. Here, the side surface 4A of the gate insulating layer 4 (the side surface 4ba of the second layer 4b) is exposed from the source electrode 5 and the drain electrode 6.

The semiconductor layer 7 covers the source electrode 5 and the drain electrode 6 as well as the gate insulating layer 4 exposed from the source electrode 5 and the drain electrode 6. Here, the side surface 2a, the gate insulating layer 4, and the source electrode 5 are exposed on the opposite side to the side where the channel region CR is present.

When viewed as the integrated thin-film transistor 11, the gate electrodes 3 each constituting the thin-film transistor 10 are configured to be integrally connected with each other on the first main surface 1a of the substrate 1 and/or on the base portion 2A of the insulating structure 2 and are also configured in an electrically integrated manner in the same manner as in the second embodiment. The source electrodes 5 each constituting the thin-film transistor 10 are configured to be integrally connected with each other on the base portion 2A of the insulating structure 2 and are also configured in an electrically integrated manner in the same manner as in the second embodiment. The drain electrodes 6 each constituting the thin-film transistor 10 are configured to be integrally connected with each other in the flat region on the tip end side of the comb tooth portions 2B and are electrically connected with each other.

(Method for Manufacturing Thin-Film Transistor and Integrated Thin-Film Transistor)

Referring to FIG. 3, a method for manufacturing the thin-film transistor and the integrated thin-film transistor in the third embodiment will be described.

[Step of Preparing Substrate]

In the step of preparing the substrate 1, a similar substrate 1 may be prepared in the same manner as in the foregoing embodiments.

[Step of Forming Insulating Structure]

The insulating structure 2 may be formed in the same manner as in the foregoing embodiments.

[Step of Forming Gate Electrode]

After forming the insulating structure 2, the gate electrode 3 is formed in the same manner as in the foregoing embodiments. The gate electrode 3 can be formed by depositing the material of the gate electrode 3 from the diagonal direction relative to the first main surface 1a of the substrate 1 by vacuum evaporation or sputtering.

In the present embodiment, the gate electrode 3 is formed on only one side of the opposing two side surfaces 2a. It is therefore necessary to deposit the material of the gate electrode 3 only from one side surface 2a side.

[Step of Forming Gate Insulating Layer]

Next, the gate insulating layer 4 is formed in the same manner as in the foregoing embodiments. In this configuration example, the gate insulating layer 4 is formed on the substrate 1 provided with the insulating structure 2 and the gate electrode 3.

First, the first layer 4a comprised in the gate insulating layer 4 is formed. In the present embodiment, the first layer 4a covering the gate electrode 3 is preferably formed in a self-alignment manner by subjecting a metal layer or a silicon layer that constitutes the gate electrode 3 to plasma treatment or heating treatment to form an oxide film or a nitride film.

Next, the second layer 4b is formed so as to cover the first layer 4a in the same manner as in the foregoing embodiments.

[Step of Forming Source Electrode and Drain Electrode]

Next, the source electrode 5 and the drain electrode 6 are formed collectively in the same manner as in the foregoing embodiments.

[Step of Forming Semiconductor Layer]

Next, the semiconductor layer 7 is formed in the same manner as in the foregoing embodiments.

Through the steps described above, the thin-film transistor 10 and the integrated thin-film transistor 11 in the third embodiment are manufactured.

### Fourth Embodiment

(Configuration Example of Thin-Film Transistor)

Referring to FIG. 4, the configuration of the thin-film transistor 10 (integrated thin-film transistor 11) in a fourth embodiment will be described. FIG. 4 is a schematic sectional view illustrating the thin-film transistor in the fourth embodiment in the same manner as in FIG. 2-2.

The thin-film transistor 10 and the integrated thin-film transistor 11 in the fourth embodiment are the configuration example in which the gate electrode 3 and the gate insulating layer 4 are provided only on the opposing two side surfaces 2a of the insulating structure 2.

In the fourth embodiment, the protrusion portion 8 is the insulating structure 2 provided on the substrate 1, the gate electrode 3 covers at least part of the side surfaces 2a of the insulating structure 2, the gate insulating layer 4 covers the gate electrode 3, the source electrode 5 and the drain electrode 6 are in contact with the gate insulating layer 4, and the semiconductor layer 7 covers the source electrode 5 and the drain electrode 6 as well as the gate insulating layer 4.

The fourth embodiment will be described more specifically. In this configuration example, three thin-film transistors 10 are provided on the substrate 1. The insulating structure 2 is provided on the first main surface 1a.

The gate electrode 3 is provided on both of the opposing two side surfaces 2a of the insulating structure 2.

The gate electrode 3 is provided in contact with the first main surface 1a of the substrate 1 so as to cover part of the side surfaces 2a. That is, the region of the side surface 2a near the top surface 2b is exposed.

The first layer 4a of the gate insulating layer 4 covers the gate electrode 3. That is, the first layer 4a covers surfaces from the first main surface 1a along the side surface 3a of the gate electrode 3 to reach part of the exposed side surface 2a. The second layer 4b covers the first layer 4a and is provided to cover surfaces from the first main surface 1a along the side surface 4aa of the first layer 4a, and cover the exposed side surface 2a of the insulating structure 2.

The source electrode 5 is provided in contact with the top surface 2b of the insulating structure 2 and the second layer 4b of the gate insulating layer 4. The drain electrode 6 is provided in the flat region where the source electrode 5 is not provided when viewed from the thickness direction of the substrate 1, that is, the first main surface 1a exposed from the insulating structure 2, the gate electrode 3, and the gate insulating layer 4. Here, the side surface 4A of the gate insulating layer 4 (the side surface 4ba of the second layer 4b) is exposed from the source electrode 5 and the drain electrode 6.

The semiconductor layer 7 is provided all over the exposed surface where the source electrode 5 and the drain electrode 6 are formed and covers the source electrode 5 and the drain electrode 6 as well as the gate insulating layer 4 exposed from the source electrode 5 and the drain electrode 6.

When viewed as the integrated thin-film transistor 11, the gate electrodes 3 each constituting the thin-film transistor 10 are configured to be integrally connected with each other on the first main surface 1a of the substrate 1 and/or on the base portion 2A of the insulating structure 2 and are also configured in an electrically integrated manner in the same manner as in the second embodiment. The source electrodes 5 each constituting the thin-film transistor 10 are configured to be integrally connected with each other on the base portion 2A of the insulating structure 2 and are also configured in an electrically integrated manner in the same manner as in the second embodiment. The drain electrodes 6 each constituting the thin-film transistor 10 are configured to be integrally connected with each other in the flat region on the tip end side of the comb tooth portions 2B and are electrically connected with each other.

It is preferable to form the gate electrode 3 not on the top surface 2b of the insulating structure 2 or the flat region but only on the side surface 2a of the insulating structure 2 as described above, because if so, the area where the source electrode 5 and the drain electrode 6 are overlapped with the gate electrode 3 with the gate insulating layer 4 interposed is reduced, and the parasitic capacity is reduced, thereby improving the speed of switching.

(Method for Manufacturing Thin-Film Transistor and Integrated Thin-Film Transistor)

Referring to FIG. 4, a method for manufacturing the thin-film transistor and the integrated thin-film transistor in the fourth embodiment will be described.

[Step of Preparing Substrate]

In the step of preparing the substrate 1, the substrate 1 having the configuration already described above is prepared in the same manner as in the foregoing embodiments.

[Step of Forming Insulating Structure]

The insulating structure 2 may be formed in the same manner as in the foregoing embodiments.

[Step of Forming Gate Electrode]

Next, the gate electrode 3 is formed in the same manner as in the foregoing embodiments. The gate electrode 3 in the present embodiment is preferably formed by self-alignment photolithography.

The step of forming the gate electrode 3 by self-alignment photolithography will be described below.

First, any given conventionally known suitable negative resist material is applied on the insulating structure 2 and the entire surface of the first main surface 1a exposed from the insulating structure 2 by a normal method to form a resist layer.

Next, an exposure step is performed by irradiating the formed resist layer with light having a wavelength and intensity depending on the resist material in the thickness direction of the substrate 1. A development step and a cleaning step are further performed to pattern the resist layer. Through the steps described above, a resist pattern that exposes only the side surfaces 2a and covers the top surface 2b of the insulating structure 2 and the flat region is formed.

Next, a layer of the material of the gate electrode 3 is formed all over the exposed surface of the substrate 1 on the side where the resist pattern is formed.

Next, the step of removing the resist pattern, such as an ashing step, depending on the selected resist material, is carried out to perform patterning for removing the resist pattern and only the layer portion of the material of the gate electrode 3 that is formed on the resist pattern and leaving only the layer portion of the material of the gate electrode 3 that is in contact with the side surfaces 2a. The gate electrode 3 having the pattern as described above is thus formed.

Through the steps described above, the gate electrode 3 can be formed only on the opposing two side surfaces 2a of the insulating structure 2.

[Step of Forming Gate Insulating Layer]

Next, the gate electrode 4 is formed in the same manner as in the foregoing embodiments. In the present embodiment, the gate insulating layer 4 is formed on the substrate 1 provided with the insulating structure 2 and the gate electrode 3.

First, the first layer 4a comprised in the gate insulating layer 4 is formed. In the present embodiment, the first layer 4a covering the gate electrode 3 is formed in a self-alignment manner by subjecting a metal layer or a silicon layer that constitutes the gate electrode 3 to plasma treatment or heating treatment to form an oxide film or a nitride film.

Next, the second layer 4b is formed so as to cover the first layer 4a in the same manner as in the foregoing embodiments.

[Step of Forming Source Electrode and Drain Electrode]

Next, the source electrode 5 and the drain electrode 6 are formed collectively in the same manner as in the foregoing embodiments.

[Step of Forming Semiconductor Layer]

Next, the semiconductor layer 7 is formed in the same manner as in the foregoing embodiments.

Through the steps described above, the thin-film transistor 10 and the integrated thin-film transistor 11 in the fourth embodiment are manufactured.

### Fifth Embodiment

(Configuration Example of Thin-Film Transistor)

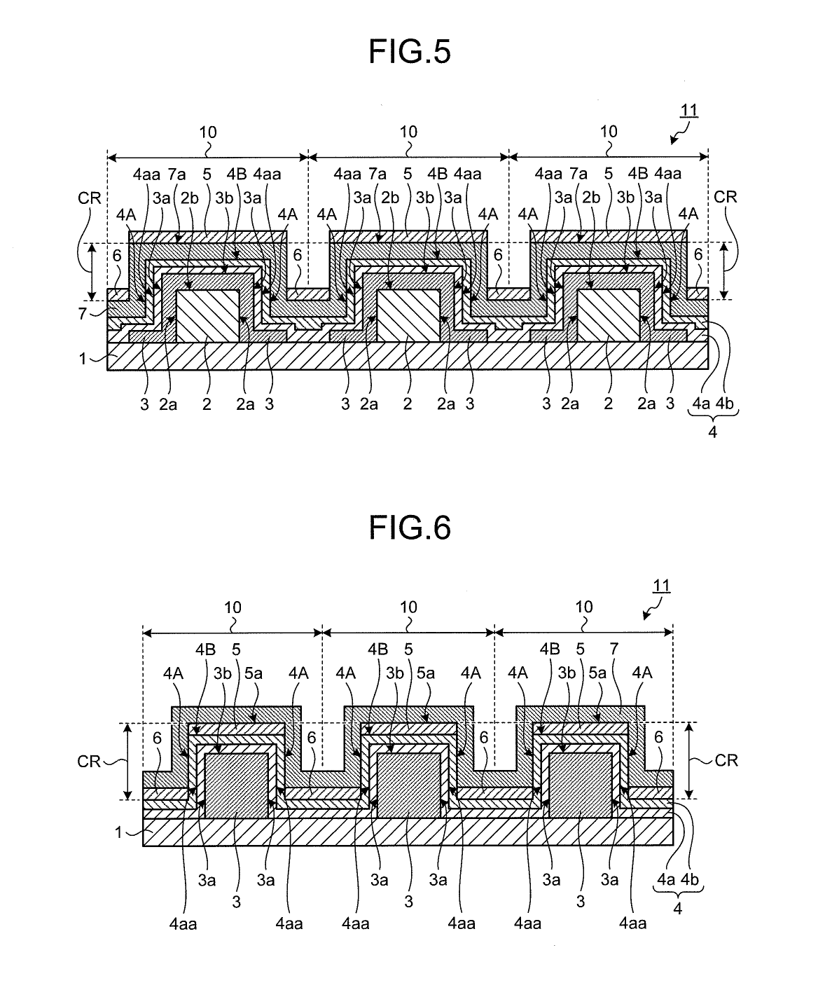

Referring to FIG. 5, the configuration of the thin-film transistor 10 (integrated thin-film transistor 11) in a fifth embodiment will be described. FIG. 5 is a schematic sectional view illustrating the thin-film transistor in the fifth embodiment in the same manner as in FIG. 2-2.

The thin-film transistor 10 and the integrated thin-film transistor 11 in the fifth embodiment are the configuration example in which the semiconductor layer 7 is provided in contact with the gate insulating layer 4, and the source electrode 5 and the drain electrode 6 are provided in contact with the semiconductor layer 7.

In the fifth embodiment, the protrusion portion 8 is the insulating structure 2 provided on the substrate 1, the gate electrode 3 covers at least part of the side surfaces 2a of the insulating structure 2, the gate insulating layer 4 covers the gate electrode 3, the semiconductor layer 7 covers the gate insulating layer 4, and the source electrode 5 and the drain electrode 6 are in contact with the semiconductor layer 7.

The fifth embodiment will be described more specifically. In this configuration example, three thin-film transistors 10 are provided on the substrate 1. The insulating structure 2 is provided on the first main surface 1a.

The gate electrode 3 is provided to extend across both of the opposing two side surfaces 2a of the insulating structure 2 in the same manner as in the first and second embodiments. The gate electrode 3 is provided to cover surfaces from the first main surface 1a exposed from the side surface 2a of the insulating structure 2 along the side surface 2a on one side of the insulating structure 2, extend from the top surface 2b to reach the side surface on the other side, and reach the first main surface 1a.

The first layer 4a of the gate insulating layer 4 covers the gate electrode 3 and is provided to cover surfaces from the first main surface 1a exposed from the gate electrode 3 along the side surface 3a of the gate electrode 3, cover the top surface 3b, and reach the exposed first main surface 1a. The second layer 4b covers the first layer 4a.

The semiconductor layer 7 covers the second layer 4b, that is, the gate insulating layer 4.

The source electrode 5 and the drain electrode 6 are in contact with the semiconductor layer 7. The source electrode 5 covers the top surface 7b of the semiconductor layer 7. The drain electrode 6 is provided in the flat region outside the top surface 7b where the source electrode 5 is not provided when viewed from the thickness direction of the substrate 1. The side surfaces 7a of the semiconductor layer 7 are exposed from the source electrode 5 and the drain electrode 6.

When viewed as the integrated thin-film transistor 11, the gate electrodes 3 each constituting the thin-film transistor 10 are configured to be integrally connected with each other on the first main surface 1a of the substrate 1 and/or on the base portion 2A of the insulating structure 2 and are also configured in an electrically integrated manner in the same manner as in the second embodiment. The source electrodes 5 each constituting the thin-film transistor 10 are configured to be integrally connected with each other on the base portion 2A of the insulating structure 2 and are also configured in an electrically integrated manner in the same manner as in the second embodiment. The drain electrodes 6 each constituting the thin-film transistor 10 are configured to be integrally connected with each other in the flat region on the tip end side of the comb tooth portions 2B and are electrically connected with each other.

In the thin-film transistor 10 in the present embodiment, the source electrode 5 and the drain electrode 6 are provided on the semiconductor layer 7 to facilitate charge injection, thereby improving the electrical characteristics of the thin-film transistor 10.

(Method for Manufacturing Thin-Film Transistor and Integrated Thin-Film Transistor)

Referring to FIG. 5, a method for manufacturing the thin-film transistor and the integrated thin-film transistor in the fifth embodiment will be described.

[Step of Preparing Substrate]

In the step of preparing the substrate 1, the substrate 1 having the configuration already described above is prepared in the same manner as in the foregoing embodiments.

[Step of Forming Insulating Structure]

The insulating structure 2 may be formed in the same manner as in the foregoing embodiments.

[Step of Forming Gate Electrode]

Next, the gate electrode 3 is formed in the same manner as in the foregoing embodiments.

[Step of Forming Gate Insulating Layer]

Next, the gate electrode 3 is formed in the same manner as in the foregoing embodiments. In the present embodiment, the gate insulating layer 4 is formed on the substrate 1 provided with the insulating structure 2 and the gate electrode 3.

First, the first layer 4a included in the gate insulating layer 4 is formed. In the present embodiment, the first layer 4a covering the gate electrode 3 is formed in a self-alignment manner by subjecting a metal layer or a silicon layer that constitutes the gate electrode 3 to plasma treatment or heating treatment to form an oxide film or a nitride film.

Next, the second layer 4b is formed so as to cover the first layer 4a in the same manner as in the foregoing embodiments.

[Step of Forming Semiconductor Layer]

Next, the semiconductor layer 7 is formed so as to cover the second layer 4b, that is, the gate insulating layer 4 in the same manner as in the foregoing embodiments.

[Step of Forming Source Electrode and Drain Electrode]

Next, the source electrode 5 and the drain electrode 6 are formed collectively on the semiconductor layer 7 in the same manner as in the foregoing embodiments.

Through the steps described above, the thin-film transistor 10 and the integrated thin-film transistor 11 in the fifth embodiment are formed.

### Sixth Embodiment

(Configuration Example of Thin-Film Transistor)

Referring to FIG. 6, the configuration of the thin-film transistor 10 (integrated thin-film transistor 11) in a sixth embodiment will be described. FIG. 6 is a schematic sectional view illustrating the thin-film transistor in the sixth embodiment in the same manner as in FIG. 2-2.

The thin-film transistor 10 and the integrated thin-film transistor 11 in the sixth embodiment are the configuration example in which the protrusion portion 8 is configured as the gate electrode 3.

In the sixth embodiment, the protrusion portion 8 is the gate electrode 3. In this configuration example, the gate electrode 3 has the same shape and size as the insulating structure 2 provided on the substrate 1 in the foregoing embodiments. The gate insulating layer 4 covers at least part of the side surfaces 3a of the gate electrode 3. The source electrode 5 and the drain electrode 6 are in contact with the gate insulating layer 4, and the semiconductor layer 7 covers the source electrode 5 and the drain electrode 6 as well as the gate insulating layer 4 exposed from the source electrode 5 and the drain electrode 6.

The sixth embodiment will be described more specifically. In this configuration example, three thin-film transistors 10 are provided on the substrate 1. The gate electrode 3 is provided on the first main surface 1a.

The gate insulating layer 4 is provided to extend across both of the opposing two side surface 3a of the gate electrode 3. That is, the first layer 4a is provided to cover surfaces from the first main surface 1a exposed from the gate electrode 3 along the side surface 3a on one side of the gate electrode 3, extend from the top surface 3b to reach the side surface 3b on the other side, and reach the first main surface 1a. The second layer 4b covers the first layer 4a.

The source electrode 5 and the drain electrode 6 are in contact with the second layer 4b, that is, the gate insulating layer 4. The source electrode 5 covers the top surface 4B of the gate insulating layer 4. The drain electrode 6 is provided in the flat region outside the top surface 4B where the source electrode 5 is not provided when viewed from the thickness direction of the substrate 1. The side surfaces 4A of the gate insulating layer 4 are exposed from the source electrode 5 and the drain electrode 6.

The semiconductor layer 7 covers the source electrode 5 and the drain electrode 6 as well as the gate insulating layer 4 exposed from the source electrode 5 and the drain electrode 6.

When viewed as the integrated thin-film transistor 11, the gate electrodes 3 each constituting the thin-film transistor 10 are configured to be integrally connected with each other on the base portion 2A of the insulating structure 2 and are also configured in an electrically integrated manner. The source electrodes 5 each constituting the thin-film transistor 10 are configured to be integrally connected with each other on the base portion 2A of the insulating structure 2 and are also configured in an electrically integrated manner in the same manner as in the second embodiment. The drain electrodes 6 each constituting the thin-film transistor 10 are configured to be integrally connected with each other in the flat region on the tip end side of the comb tooth portions 2B and are electrically connected with each other.

(Method for manufacturing Thin-Film Transistor and Integrated Thin-Film Transistor)

Referring to FIG. 6, a method for manufacturing the thin-film transistor and the integrated thin-film transistor in the sixth embodiment will be described.

[Step of Preparing Substrate]

In the step of preparing the substrate 1, the substrate 1 having the configuration already described above is prepared in the same manner as in the foregoing embodiments.

Next, the gate electrode 3 is formed. The gate electrode 3 can be formed through the same step as a conventionally known wiring forming step in a wafer process, using the same material as in the foregoing embodiments.

[Step of Forming Gate Insulating Layer]

Next, the gate insulating layer 4 is formed in the same manner as in the foregoing embodiments. In this embodiment, the gate insulating layer 4 is formed on the substrate 1 provided with the gate electrode 3.

First, the first layer 4a comprised in the gate insulating layer 4 is formed. In the present embodiment, the first layer 4a can be formed, for example, by vacuum evaporation method, sputtering method, pulsed laser deposition method, atomic layer deposition method, organometallic chemical vapor deposition method, molecular beam epitaxy method, electron beam evaporation method, chemical vapor deposition, anodic oxidation method, thermal oxidation method, plasma treatment method, coating methods, or printing methods, as previously described.

Next, the second layer 4b is formed so as to cover the first layer 4a in the same manner as in the foregoing embodiments.

[Step of Forming Source Electrode and Drain Electrode]

Next, the source electrode 5 and the drain electrode 6 are formed collectively so as to cover the second layer 4b, that is, the gate insulating layer 4 in the same manner as in the foregoing embodiments.

[Step of Forming Semiconductor Layer]

Next, the semiconductor layer 7 that covers the source electrode 5 and the drain electrode 6 as well as the gate insulating layer 4 exposed therefrom is formed in the same manner as in the foregoing embodiments.

Through the steps described above, the thin-film transistor 10 and the integrated thin-film transistor 11 in the sixth embodiment are formed.

According to the method for manufacturing the thin-film transistor 10 in the sixth embodiment, the thin-film transistor 10 can be manufactured in a simpler way because the step of forming the insulating structure 2 is not required.

### Seventh Embodiment

### Configuration Example of Thin-Film Transistor

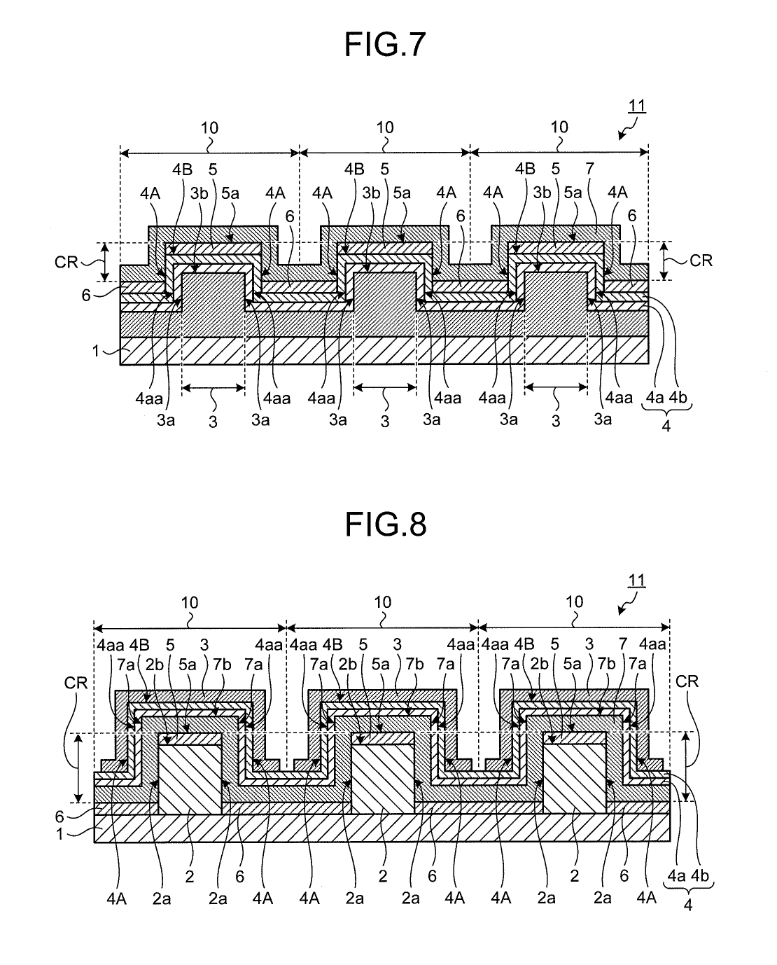

Referring to FIG. 7, the configuration of the thin-film transistor 10 (integrated thin-film transistor 11) in a seventh embodiment will be described. FIG. 7 is a schematic sectional view illustrating the thin-film transistor in the seventh embodiment in the same manner as in FIG. 2-2.

The thin-film transistor 10 and the integrated thin-film transistor 11 in the seventh embodiment are the configuration example in which the protrusion portion 8 is configured as the gate electrode 3.

In the seventh embodiment, the protrusion portion 8 is the gate electrode 3. In this configuration example, the gate electrode 3 has the same shape and size as the insulating structure 2 provided on the substrate 1 in the foregoing embodiments. The gate insulating layer 4 covers at least part of the side surfaces 3a of the gate electrode 3. The source electrode 5 and the drain electrode 6 are in contact with the gate insulating layer 4, and the semiconductor layer 7 covers the source electrode 5 and the drain electrode 6 as well as the gate insulating layer 4 exposed from the source electrode 5 and the drain electrode 6.

The seventh embodiment will be described more specifically. In this configuration example, three thin-film transistors 10 are provided on the substrate 1. The gate electrode 3 is provided on the first main surface 1a.

In this configuration example, the gate electrode 3 extends even in the region outside the protrusion portion 8, that is, in the flat region one level lower than the protrusion portion 8 in the thickness direction of the substrate 1, where the protrusion portion 8 is not to be formed. Three gate electrodes 3 on the substrate 1 are integrally configured and are electrically connected with each other.

A silicon substrate doped with an n-type or p-type impurity at a high concentration may be used as the gate electrode 3. The silicon substrate doped with an n-type or p-type impurity at a high concentration has an electrical function as the gate electrode 3 and a function as the substrate 1. When a silicon substrate doped with an impurity at a high concentration is used as a configuration serving both as the gate electrode 3 and as the substrate 1, the substrate 1 may be omitted. In this case, the thickness of the gate electrode 3 is preferably 0.02 μm to 100 rim.

The gate insulating layer 4 integrally covers three gate electrodes 3. That is, the first layer 4a covers not only the two side surfaces 3a and the top surface 3b of the gate electrode 3 but also the flat region. The second layer 4b further covers the first layer 4a, and the region that covers the side surface 4aa of the first layer 4a serves as the side surface 4A of the gate insulating layer 4.

The source electrode 5 and the drain electrode 6 are in contact with the second layer 4b, that is, the gate insulating layer 4. The source electrode 5 covers the top surface 4B of the gate insulating layer 4. The drain electrode 6 is provided in the flat region outside the top surface 4B where the source electrode 5 is not provided when viewed from the thickness direction of the substrate 1. The side surfaces 4A of the gate insulating layer 4 are exposed from the source electrode 5 and the drain electrode 6.

The semiconductor layer 7 covers the source electrode 5 and the drain electrode 6 as well as the gate insulating layer 4 exposed from the source electrode 5 and the drain electrode 6.

When viewed as the integrated thin-film transistor 11, the gate electrodes 3 each constituting the thin-film transistor 10 are configured to be integrally connected with each other in the flat region between the adjacent gate electrodes 3 and are also configured in an electrically integrated manner, as already described above. The source electrodes 5 each constituting the thin-film transistor 10 are configured to be integrally connected with each other on the base portion 2A of the insulating structure 2 and are also configured in an electrically integrated manner in the same manner as in the second embodiment. The drain electrodes 6 each constituting the thin-film transistor 10 are configured to be integrally connected with each other in the flat region on the tip end side of the comb tooth portions 2B and are electrically connected with each other.

(Method for Manufacturing Thin-Film Transistor and Integrated Thin-Film Transistor)

Referring to FIG. 7, a method for manufacturing the thin-film transistor and the integrated thin-film transistor in the seventh embodiment will be described.

[Step of Preparing Substrate]

In the step of preparing the substrate 1, the substrate 1 having the configuration already described above is prepared in the same manner as in the foregoing embodiments.

Next, the gate electrode 3 is formed. The gate electrode 3 can be formed through the same step as a conventionally-known wiring forming step in a wafer process, using the same material as in the foregoing embodiments.

In this embodiment, the gate electrode 3 may be formed by patterning a silicon substrate doped with an n-type or p-type impurity at a high concentration as described above, for example, through an etching step.

[Step of Forming Gate Insulating Layer]

Next, the gate electrode 4 is formed in the same manner as in the foregoing embodiments. In this embodiment, the gate insulating layer 4 is formed on the substrate 1 provided with the gate electrode 3.

First, the first layer 4a comprised in the gate insulating layer 4 is formed. In the present embodiment, the first layer 4a can be formed, for example, by vacuum evaporation method, sputtering method, pulsed laser deposition method, atomic layer deposition method, organometallic chemical vapor deposition method, molecular beam epitaxy method, electron beam evaporation method, chemical vapor deposition, anodic oxidation method, thermal oxidation method, plasma treatment method, coating methods, or printing methods, as previously described.

When the silicon substrate doped with an impurity at a high concentration is used as a configuration serving both as the gate electrode 3 and as the substrate 1, the silicon substrate doped with an impurity at a high concentration to serve as the gate electrode 3 and the substrate 1 may be subjected to plasma treatment or heating treatment to form an oxide film or a nitride film. When the first layer 4a is formed as described above, the first layer 4a covering the gate electrode 3 can be formed in a self-alignment manner.

Next, the second layer 4b is formed so as to cover the first layer 4a in the same manner as in the foregoing embodiments.

[Step of Forming Source Electrode and Drain Electrode]

Next, the source electrode 5 and the drain electrode 6 are formed collectively so as to cover the second layer 4b, that is, the gate insulating layer 4 in the same manner as in the foregoing embodiments.

[Step of Forming Semiconductor Layer]

Next, the semiconductor layer 7 that covers the source electrode 5 and the drain electrode 6 as well as the gate insulating layer 4 exposed therefrom is formed in the same manner as in the foregoing embodiments.

Through the steps described above, the thin-film transistor 10 and the integrated thin-film transistor 11 in the sixth embodiment are formed.

According to the method for manufacturing the thin-film transistor 10 in the seventh embodiment, the thin-film transistor 10 can be manufactured in a simpler way because the step of forming the insulating structure 2 is not required.

### Eighth Embodiment

(Configuration Example of Thin-Film Transistor)

Referring to FIG. 8, the configuration of the thin-film transistor 10 (integrated thin-film transistor 11) in an eighth embodiment will be described. FIG. 8 is a schematic sectional view illustrating the thin-film transistor in the eighth embodiment in the same manner as in FIG. 2-2.

The thin-film transistor 10 and the integrated thin-film transistor 11 in the eighth embodiment are the configuration example of a top gate-type thin-film transistor, which is provided on the substrate 1, comprising: the insulating structure 2 that is the column-shaped protrusion portion 8 protruding from the first main surface 1a of the substrate 1 and having the side surface 2a with a shorter direction that corresponds to the direction that approximately corresponds to the thickness direction of the substrate 1 and with a longer direction that is the direction orthogonal to the thickness direction of the substrate 1; the source electrode 5 and the drain electrode 6 electrically isolated from each other, when viewed from the thickness direction of the substrate 1, one of the source electrode 5 and the drain electrode 6 being provided to overlap the insulating structure 2 and the other being provided in the remaining region; the semiconductor layer 7 that covers the source electrode 5 and the drain electrode 6 as well as the side surface 2a exposed from the source electrode 5 and the drain electrode 6; the gate insulating layer 4 with a thickness of 50 nm or less that covers the semiconductor layer 7 and comprises the first layer 4a that is a metal oxide layer, a metal nitride layer, a silicon oxide layer, or a silicon nitride layer, and the second layer 4b that is a self-assembled monomolecular layer; and the gate electrode 3 that is in contact with the gate insulating layer 4 and extends across the protrusion portion 8.

As illustrated in FIG. 8, the integrated thin-film transistor 11 comprises three thin-film transistors 10. These three thin-film transistors 10 are arranged at regular intervals.

In this configuration example, the insulating structure 2 is provided on the first main surface 1a of the substrate 1 in the same manner as in the foregoing embodiments.

In this configuration example, the source electrode 5 is provided to cover only the top surface 2b of the insulating structure 2. The drain electrode 6 is formed in the remaining region where the insulating structure 2 and the source electrode 5 are not formed on the first main surface 1a of the substrate 1, that is, only in the flat region, and is electrically isolated from the source electrode 5 in the thickness direction of the substrate 1.

The semiconductor layer 7 covers the source electrode 5 and the drain electrode 6 as well as the two opposing side surfaces 2a of the insulating structure 2 exposed from the source electrode 5 and the drain electrode 6.

The gate insulating layer 4 integrally covers the semiconductor layer 7. That is, the first layer 4a covers not only the two side surfaces 7a and the top surface 7b of the semiconductor layer 7 but also the flat region. The second layer 4b covers the first layer 4a, and the region that covers the side surface 4aa of the first layer 4a serves as the side surface 4A of the gate insulating layer 4.

The gate electrode 3 is in contact with the second layer 4b, that is, the gate insulating layer 4 so as to extend across the protrusion portion 8, that is, the insulating structure 2, the top surface 7b of the semiconductor layer 7, and the top surface 4B of the insulating layer 4.

The gate electrode 3 is provided to extend from the flat region on one side surface 2a side to reach the flat region on the other side surface 2a side. The gate electrodes 3 extending across three insulating structures 2 are spaced apart from each other in the flat region between the adjacent gate electrodes 3.

When viewed as the integrated thin-film transistor 11, the gate electrodes 3 each constituting the thin-film transistor 10 are configured to be integrally connected with each other on the base portion 2A of the insulating structure 2 and are also configured in an electrically integrated manner in the same manner as in the second embodiment, as already described above. The source electrodes 5 each constituting the thin-film transistor 10 are configured to be integrally connected with each other on the base portion 2A of the insulating structure 2 and are also configured in an electrically integrated manner in the same manner as in the second embodiment. The drain electrodes 6 each constituting the thin-film transistor 10 are configured to be integrally connected with each other in the flat region on the tip end side of the comb tooth portions 2B and are electrically connected with each other.

Because the thin-film transistor 10 in the eighth embodiment has a top-gate type structure, the electrical characteristics can be further improved.

(Method for Manufacturing Thin-Film Transistor and Integrated Thin-Film Transistor)

Referring to FIG. 8, a method for manufacturing the thin-film transistor and the integrated thin-film transistor in the eighth embodiment will be described.

[Step of Preparing Substrate]

In the step of preparing the substrate 1, the substrate 1 having the configuration already described above is prepared in the same manner as in the foregoing embodiments.

[Step of Forming Insulating Structure]

Next, the insulating structure 2 is formed. The insulating structure 2 can be formed in the same manner as in the foregoing embodiments.

[Step of Forming Source Electrode and Drain Electrode]

Next, the source electrode 5 and the drain electrode 6 are formed collectively in the same manner as in the foregoing embodiments. In this configuration example, the source electrode 5 is formed so as to cover the top surface 2b of the insulating structure 2, and the drain electrode 6 is formed only in the flat region that is the remaining region. The source electrode 5 and the drain electrode 6 are thus electrically isolated from each other in the thickness direction of the substrate 1.

[Step of Forming Semiconductor Layer]

Next, the semiconductor layer 7 that covers the source electrode 5 and the drain electrode 6 as well as the opposing two side surfaces 2a of the insulating structure 2 exposed therefrom is formed in the same manner as in the foregoing embodiments.

[Step of Forming Gate Insulating Layer]

Next, the gate insulating layer 4 is formed in the same manner as in the foregoing embodiments. In this embodiment, the gate insulating layer 4 is formed so as to cover the semiconductor layer 7.

First, the first layer 4a comprised in the gate insulating layer 4 is formed. In the present embodiment, the first layer 4a can be formed, for example, by vacuum evaporation method, sputtering method, pulsed laser deposition, atomic layer deposition, organometallic chemical vapor deposition method, molecular beam epitaxy method, electron beam evaporation method, chemical vapor deposition, anodic oxidation method, thermal oxidation method, plasma treatment method, coating methods, or printing methods, as previously described.

Next, the second layer 4b is formed so as to cover the first layer 4a in the same manner as in the foregoing embodiments.

[Step of Forming Gate Electrode]

Next, the gate electrode 3 is formed. The gate electrode 3 can be formed so as to be in contact with at least part of the side surfaces 2a and the top surface 2b of the insulating structure 2 in this configuration example, by depositing the material of the gate electrode 3 from the diagonal direction relative to the first main surface 1a of the substrate 1 by a formation method such as vacuum evaporation method or sputtering method, in the same manner as in the foregoing embodiments. Specifically, after the material is deposited from one side surface 2a side, the step of forming the gate electrode 3 is performed from the opposing other side surface 2a side with the angle changed. These steps are repeated multiple times, if necessary. Alternatively, the gate electrode 3 can be formed while rotating the substrate 1.

Through the steps described above, the thin-film transistor 10 and the integrated thin-film transistor 11 in the eighth embodiment are formed.

### Ninth Embodiment

### Configuration Example of Thin-Film Transistor

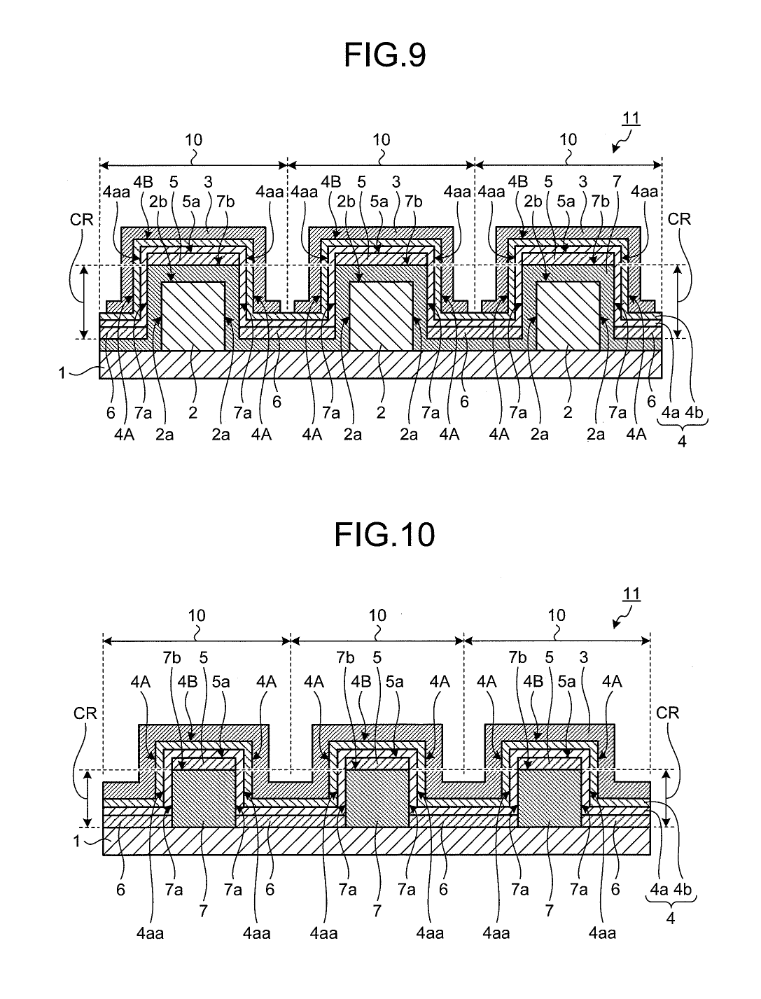

Referring to FIG. 9, the configuration of the thin-film transistor 10 (integrated thin-film transistor 11) in a ninth embodiment will be described. FIG. 9 is a schematic sectional view illustrating the thin-film transistor in the ninth embodiment in the same manner as in FIG. 2-2.

The thin-film transistor 10 and the integrated thin-film transistor 11 in the ninth embodiment are the configuration example of a top gate-type thin-film transistor, in which the semiconductor layer 7 covers the substrate 1 and the protrusion portion 8 provided on the substrate 1, the source electrode 5 and the drain electrode 6 are in contact with the semiconductor layer 7, the gate insulating layer 4 covers the source electrode 5 and the drain electrode 6 as well as the semiconductor layer 7 exposed from the source electrode 5 and the drain electrode 6.

As illustrated in FIG. 9, the integrated thin-film transistor 11 comprises three thin-film transistors 10. These three thin-film transistors 10 are arranged at regular intervals.

In this configuration example, the insulating structure 2 is provided on the first main surface 1a of the substrate 1 in the same manner as in the foregoing embodiments.

The semiconductor layer 7 covers the two opposing side surfaces 2a and the top surface 2b of the insulating structure 2. In this configuration example, the semiconductor layer 7 is provided to cover three insulating structures 2 and the first main surface 1a exposed from the insulating structures 2.

The source electrode 5 is provided to cover only the top surface 7b of the semiconductor layer 7. The drain electrode 6 is formed only in the flat region that is the remaining region where the source electrode 5 is not to be formed, and is electrically isolated from the source electrode 5 in the thickness direction of the substrate 1.

The gate insulating layer 4 integrally covers the source electrode 5, the drain electrode 6, and the side surfaces 7a of the semiconductor layer 7 exposed from the source electrode 5 and the drain electrode 6. That is, the first layer 4a covers not only the two side surfaces 7a of the semiconductor layer 7 but also the flat region. The second layer 4b covers the first layer 4a, and the region that covers the side surface 4aa of the first layer 4a serves as the side surface 4A of the gate insulating layer 4.

The gate electrode 3 is in contact with the second layer 4b, that is, the gate insulating layer 4 so as to extend across the protrusion portion 8, that is, the insulating structure 2, the top surface 7b of the semiconductor layer 7, and the top surface 4B of the insulating layer 4.

The gate electrode 3 is provided to extend from the flat region on one side surface 2b side to reach the flat region on the other side surface 2b side. The gate electrodes 3 extending across three insulating structures 2 are spaced apart from each other in the flat region between the adjacent gate electrodes 3.

When viewed as the integrated thin-film transistor 11, the gate electrodes 3 each constituting the thin-film transistor 10 are configured in the same manner as in the eighth embodiment, as already described above. The source electrodes 5 each constituting the thin-film transistor 10 are configured to be integrally connected with each other on the base portion 2A of the insulating structure 2 and are also configured in an electrically integrated manner in the same manner as in the second embodiment. The drain electrodes 6 each constituting the thin-film transistor 10 are configured to be integrally connected with each other in the flat region on the tip end side of the comb tooth portions 2B and are electrically connected with each other.

Because the thin-film transistor 10 in the ninth embodiment has a top-gate structure, the electrical characteristics can be further improved.

(Method for Manufacturing Thin-Film Transistor and Integrated Thin-Film Transistor)

Referring to FIG. 9, a method for manufacturing the thin-film transistor and the integrated thin-film transistor in the ninth embodiment will be described.

[Step of Preparing Substrate]

In the step of preparing the substrate 1, the substrate 1 having the configuration already described above is prepared in the same manner as in the foregoing embodiments.

[Step of Forming Insulating Structure]

Next, the insulating structure 2 is formed. The insulating structure 2 can be formed in the same manner as in the foregoing embodiments.

[Step of Forming Semiconductor Layer]

Next, the semiconductor layer 7 is formed so as to integrally cover three insulating structures 2 in the same manner as in the foregoing embodiments. That is, the semiconductor layer 7 is formed so as to cover the insulating structure 2 and the first main surface 1a exposed therefrom.

[Step of Forming Source Electrode and Drain Electrode]

Next, the source electrode 5 and the drain electrode 6 are formed collectively in the same manner as in the foregoing embodiments. In this configuration example, the source electrode 5 is formed so as to cover the top surface 7b of the semiconductor layer 7, and the drain electrode 6 is formed only in the semiconductor layer 7 in the flat region that is the remaining region. The source electrode 5 and the drain electrode 6 are thus electrically isolated from each other in the thickness direction of the substrate 1.

[Step of Forming Gate Insulating Layer]

Next, the gate insulating layer 4 is formed in the same manner as in the foregoing embodiments. In this embodiment, the gate insulating layer 4 is formed so as to cover the source electrode 5 and the drain electrode 6 as well as the side surfaces 7a of the semiconductor layer 7 exposed from the source electrode 5 and the drain electrode 6.

First, the first layer 4a comprised in the gate insulating layer 4 is formed. In the present embodiment, the first layer 4a can be formed, for example, by vacuum evaporation method, sputtering method, pulsed laser deposition method, atomic layer deposition method, organometallic chemical vapor deposition method, molecular beam epitaxy method, electron beam evaporation method, chemical vapor deposition, anodic oxidation method, thermal oxidation method, plasma treatment method, coating methods, or printing methods, as previously described.

Next, the second layer 4b is formed so as to cover the first layer 4a in the same manner as in the foregoing embodiments.

[Step of Forming Gate Electrode]

Next, the gate electrode 3 is formed. The gate electrode 3 can be formed so as to be in contact with at least part of the side surfaces 2a and the top surface 2b of the insulating structure 2 in this configuration example, by depositing the material of the gate electrode 3 from the diagonal direction relative to the first main surface 1a of the substrate 1 by a formation method such as vacuum evaporation method or sputtering method, in the same manner as in the foregoing embodiments. Specifically, after the material is deposited from one side surface 2a side, the step of forming the gate electrode 3 is performed from the opposing other side surface 2a side with the angle changed. These steps are repeated multiple times, if necessary. Alternatively, the gate electrode 3 can be formed while rotating the substrate 1.

Through the steps described above, the thin-film transistor 10 and the integrated thin-film transistor 11 in the ninth embodiment are formed.

### Tenth Embodiment

### Configuration Example of Thin-Film Transistor

Referring to FIG. 10, the configuration of the thin-film transistor 10 (integrated thin-film transistor 11) in a tenth embodiment will be described. FIG. 10 is a schematic sectional view illustrating the thin-film transistor in the tenth embodiment in the same manner as in FIG. 2-2.

The thin-film transistor 10 and the integrated thin-film transistor 11 in the tenth embodiment are the configuration example in which the protrusion portion 8 is configured as the semiconductor layer 7. Specifically, the protrusion portion 8 is the semiconductor layer 7 provided on the substrate 1, the gate insulating layer 4 is provided to cover at least part of the side surfaces 7a of the semiconductor layer 7, and the gate electrode 3 covers the gate insulating layer 4.

In the tenth embodiment, the protrusion portion 8 is the semiconductor layer 7. In this configuration example, the semiconductor layer 7 has the same shape and size as the insulating structure 2 provided on the substrate 1 in the foregoing embodiments.

In this configuration example, three thin-film transistors 10 are provided on the substrate 1. The semiconductor layer 7 is provided on the first main surface 1a.

The source electrode 5 and the drain electrode 6 are in contact with the semiconductor layer 7. The source electrode 5 covers the top surface 7b of the semiconductor layer 7. The drain electrode 6 is in contact with the flat region outside the top surface 7b where the source electrode 5 is not provided when viewed from the thickness direction of the substrate 1, that is, the exposed first main surface 1a. The side surfaces 7a of the semiconductor layer 7 are exposed from the source electrode 5 and the drain electrode 6.

The gate insulating layer 4 integrally covers the source electrode 5 and the drain electrode 6 as well as the side surfaces 7a of the semiconductor layer 7 exposed from the source electrode 5 and the drain electrode 6. The second layer 4b covers the first layer 4a, and the region that covers the side surface 4aa of the first layer 4a serves as the side surface 4A of the gate insulating layer 4.

The gate electrode 3 covers the second layer 4b, that is, the gate insulating layer 4 so as to extend across the protrusion portion 8, that is, the top surface 7b of the semiconductor layer 7, the top surface 5a of the source electrode 5, and the top surface 4B of the insulating layer 4.

When viewed as the integrated thin-film transistor 11, the gate electrodes 3 each constituting the thin-film transistor 10 are configured to be integrally connected with each other and are also configured in an electrically integrated manner as already described above. The source electrodes 5 each constituting the thin-film transistor 10 are configured to be integrally connected with each other on the base portion 2A of the insulating structure 2 and are also configured in an electrically integrated manner in the same manner as in the second embodiment. The drain electrodes 6 each constituting the thin-film transistor 10 are configured to be integrally connected with each other in the flat region on the tip end side of the comb tooth portions 2B and are electrically connected with each other.

(Method for Manufacturing Thin-Film Transistor and Integrated Thin-Film Transistor)

Referring to FIG. 10, a method for manufacturing the thin-film transistor and the integrated thin-film transistor in the tenth embodiment will be described.

[Step of Preparing Substrate]

In the step of preparing the substrate 1, the substrate 1 having the configuration already described above is prepared in the same manner as in the foregoing embodiments.

Next, the semiconductor layer 7 is formed. The semiconductor layer 7 in the present embodiment can be formed, for example, by patterning by a conventionally known patterning method, such as (nano)imprinting, in which a layer is formed so as to cover the entire exposed surface using the material as described above and pressed against a mold for forming a desired pattern to be patterned.

To form the semiconductor layer 7, photolithography and printing methods may also be used. As the printing methods, inkjet printing method, screen printing method, flexographic printing method, offset printing method, dispenser printing method, nozzle coating method, capillary coating method, gravure coating method, microcontact printing method, and gravure/offset printing method are preferred.

[Step of Forming Source Electrode and Drain Electrode]

Next, the source electrode 5 and the drain electrode 6 are formed collectively in the same manner as in the foregoing embodiments. In this configuration example, the source electrode 5 is formed so as to cover the top surface 7b of the semiconductor layer 7, and the drain electrode 6 is formed only in the first main surface 1a exposed in the flat region that is the remaining region. The source electrode 5 and the drain electrode 6 are thus electrically isolated from each other in the thickness direction of the substrate 1.

[Step of Forming Gate Insulating Layer]

Next, the gate insulating layer 4 is formed in the same manner as in the foregoing embodiments. In this embodiment, the gate insulating layer 4 is formed so as to cover the source electrode 5 and the drain electrode 6 as well as the side surfaces 7a of the semiconductor layer 7 exposed from the source electrode 5 and the drain electrode 6.

First, the first layer 4a comprised in the gate insulating layer 4 is formed. In the present embodiment, the first layer 4a can be formed, for example, by vacuum evaporation method, sputtering method, pulsed laser deposition method, atomic layer deposition method, organometallic chemical vapor deposition method, molecular beam epitaxy method, electron beam evaporation method, chemical vapor deposition, anodic oxidation method, thermal oxidation method, plasma treatment method, coating methods, or printing methods, as previously described.

Next, the second layer 4b is formed so as to cover the first layer 4a in the same manner as in the foregoing embodiments.

[Step of Forming Gate Electrode]

Next, the gate electrode 3 is formed. The gate electrode 3 can be formed by depositing the material of the gate electrode 3 by a formation method such as vacuum evaporation and sputtering in the same manner as in the foregoing embodiments. In this embodiment, because the gate electrode 3 is formed so as to cover the entire surface of the gate insulating layer 4, the gate electrode 3 can be formed without relying on the deposition from the diagonal direction as described above and thus can also be formed through a simpler step such as coating.

Through the steps described above, the thin-film transistor 10 and the integrated thin-film transistor 11 in the tenth embodiment are formed.

With the method for manufacturing the thin-film transistor 10 in the tenth embodiment, the thin-film transistor 10 can be manufactured in a simpler way because the step of forming the insulating structure 2 is not required.

### Eleventh Embodiment

### Configuration Example of Thin-Film Transistor

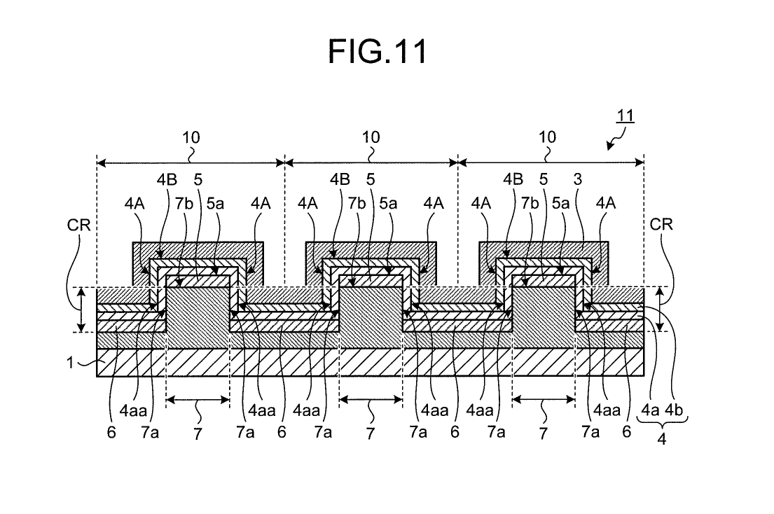

Referring to FIG. 11, the configuration of the thin-film transistor 10 (integrated thin-film transistor 11) in an eleventh embodiment will be described. FIG. 11 is a schematic sectional view illustrating the thin-film transistor in the eleventh embodiment in the same manner as in FIG. 2-2.

The thin-film transistor 10 and the integrated thin-film transistor 11 in the eleventh embodiment are the configuration example in which the protrusion portion 8 is configured as the semiconductor layer 7. Specifically, the protrusion portion 8 is the semiconductor layer 7 provided on the substrate 1 and integrally configured to cover even the flat region outside the protrusion portion 8. The gate insulating layer 4 is provided to cover at least part of the side surfaces 7a of the semiconductor layer 7. The gate electrode 3 covers the gate insulating layer 4.

In the eleventh embodiment, the protrusion portion 8 is the semiconductor layer 7. In this configuration example, the semiconductor layer 7 as the protrusion portion 8 has the same shape and size as the insulating structure 2 provided on the substrate 1 in the foregoing embodiments.

In this configuration example, the semiconductor layer 7 is integrally configured to further cover even the one-level lower flat region outside the protrusion portion 8.

In this configuration example, three thin-film transistors 10 are provided on the substrate 1. The semiconductor layer 7 is provided on the first main surface 1a.

The source electrode 5 and the drain electrode 6 are in contact with the semiconductor layer 7. The source electrode 5 covers the top surface 7b of the semiconductor layer 7. The drain electrode 6 is in contact with the semiconductor layer 7 in the flat region outside the top surface 7b where the source electrode 5 is not provided when viewed from the thickness direction of the substrate 1. The side surfaces 7a of the semiconductor layer 7 are exposed from the source electrode 5 and the drain electrode 6.

The gate insulating layer 4 integrally covers the source electrode 5 and the drain electrode 6 as well as the side surfaces 7a of the semiconductor layer 7 exposed from the source electrode 5 and the drain electrode 6. The second layer 4b covers the first layer 4a, and the region that covers the side surface 4aa of the first layer 4a serves as the side surface 4A of the gate insulating layer 4.

The gate electrode 3 covers the second layer 4b, that is, the gate insulating layer 4 so as to extend across the protrusion portion 8, that is, the top surface 7b of the semiconductor layer 7, the top surface 5a of the source electrode 5, and the top surface 4B of the insulating layer 4.

When viewed as the integrated thin-film transistor 11, the gate electrodes 3 each constituting the thin-film transistor 10 are configured to be integrally connected with each other and are also configured in an electrically integrated manner as already described above. The source electrodes 5 each constituting the thin-film transistor 10 are configured to be integrally connected with each other on the base portion 2A of the insulating structure 2 and are also configured in an electrically integrated manner in the same manner as in the second embodiment. The drain electrodes 6 each constituting the thin-film transistor 10 are configured to be integrally connected with each other in the flat region on the tip end side of the comb tooth portions 2B and are electrically connected with each other.

(Method for Manufacturing Thin-Film Transistor and Integrated Thin-Film Transistor)

Referring to FIG. 11, a method for manufacturing the thin-film transistor and the integrated thin-film transistor in the eleventh embodiment will be described.

[Step of Preparing Substrate]

In the step of preparing the substrate 1, the substrate 1 having the configuration already described above is prepared in the same manner as in the foregoing embodiments.

[Step of Forming Semiconductor Layer]

Next, the semiconductor layer 7 is formed. The semiconductor layer 7 in the present embodiment can be formed, for example, by patterning by a conventionally-known patterning method, such as (nano)imprinting, in which a layer is formed so as to cover the entire exposed surface using the material as described above and pressed against a mold for forming a desired pattern to be patterned.

To form the semiconductor layer 7, photolithography and printing methods may also be used. As the printing methods, inkjet printing method, screen printing method, flexographic printing method, offset printing method, dispenser printing method, nozzle coating method, capillary coating method, gravure coating method, microcontact printing method, and gravure/offset printing method are preferred.

[Step of Forming Source Electrode and Drain Electrode]

Next, the source electrode 5 and the drain electrode 6 are formed collectively in the same manner as in the foregoing embodiments. In this configuration example, the source electrode 5 is formed so as to cover the top surface 7b of the semiconductor layer 7, and the drain electrode 6 is formed on the semiconductor layer 7 in the flat region that is the remaining region. The source electrode 5 and the drain electrode 6 are thus electrically isolated from each other in the thickness direction of the substrate 1.

[Step of Forming Gate Insulating Layer]

Next, the gate insulating layer 4 is formed in the same manner as in the foregoing embodiments. In this embodiment, the gate insulating layer 4 is formed so as to cover the source electrode 5 and the drain electrode 6 as well as the side surfaces 7a of the semiconductor layer 7 exposed from the source electrode 5 and the drain electrode 6.

First, the first layer 4a comprised in the gate insulating layer 4 is formed. In the present embodiment, the first layer 4a can be formed, for example, by vacuum evaporation method, sputtering method, pulsed laser deposition method, atomic layer deposition method, organometallic chemical vapor deposition method, molecular beam epitaxy method, electron beam evaporation method, chemical vapor deposition, anodic oxidation method, thermal oxidation method, plasma treatment method, coating methods, or printing methods, as previously described.

Next, the second layer 4b is formed so as to cover the first layer 4a in the same manner as in the foregoing embodiments.

[Step of Forming Gate Electrode]

Next, the gate electrode 3 is formed. The gate electrode 3 can be formed by depositing the material of the gate electrode 3 by a formation method such as vacuum evaporation method and sputtering method in the same manner as in the foregoing embodiments. In this embodiment, because the gate electrode 3 is formed so as to cover the entire surface of the gate insulating layer 4, the gate electrode 3 can be formed without relying on the deposition from the diagonal direction as described above and thus can also be formed through a simpler step such as coating.

Through the steps described above, the thin-film transistor 10 and the integrated thin-film transistor 11 in the eleventh embodiment are formed.

According to the method for forming the thin-film transistor 10 in the eleventh embodiment, the thin-film transistor 10 can be manufactured in a simpler way because the step of forming the insulating structure 2 is not required.

### Twelfth Embodiment

### Configuration Example of Thin-Film Transistor

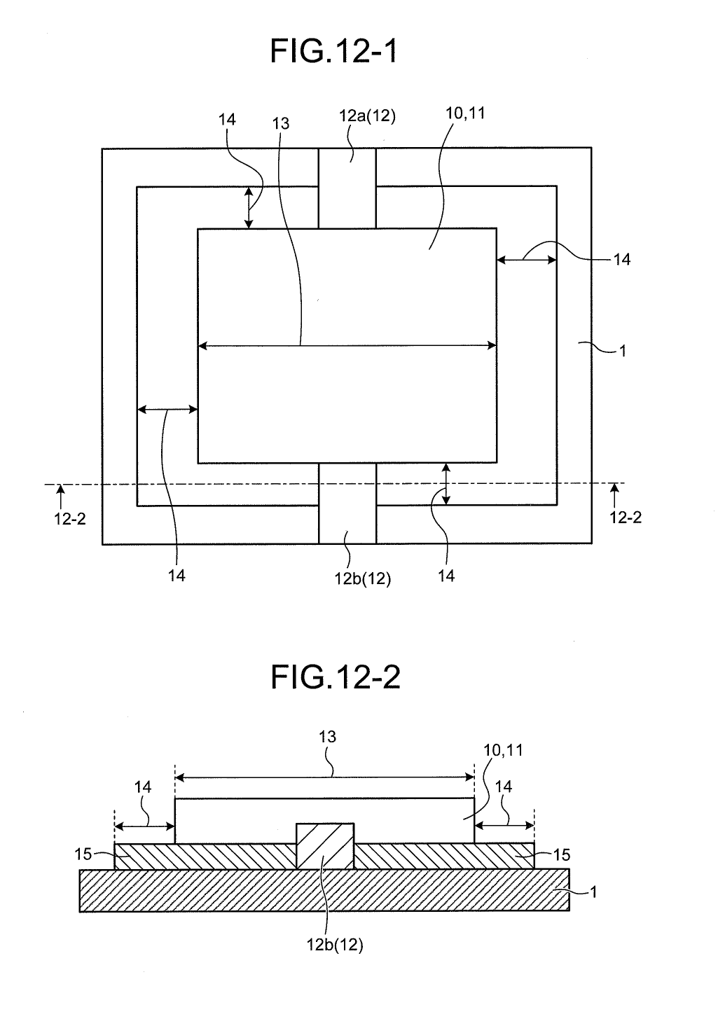

Referring to FIG. 12-1 and FIG. 12-2, the configuration of the thin-film transistor 10 (integrated thin-film transistor 11) in a twelfth embodiment will be described. FIG. 12-1 is a schematic plan view of the thin-film transistor in the twelfth embodiment. FIG. 12-2 is a schematic sectional view of the thin-film transistor in the twelfth embodiment.

As illustrated in FIG. 12-1 and FIG. 12-2, the twelfth embodiment is characterized by a configuration provided on the periphery of the thin-film transistor 10 and the integrated thin-film transistor 11. That is, the thin-film transistor 10 and the integrated thin-film transistor 11 according to the twelfth embodiment have connection wiring 12 that extends to the outside of a thin-film transistor-formed region 13 where the thin-film transistor 10 is provided, when viewed from the thickness direction of the substrate 1, and is connected with each of the source electrode 5 and the drain electrode 6. The gate electrode 3 and the gate insulating layer 4 have a spread portion 14 that spreads out of the thin-film transistor-formed region 13 when viewed from the thickness direction of the substrate 1.

The configuration examples in the first to eleventh embodiments described above can be employed as the configuration of the thin-film transistor 10 and the integrated thin-film transistor 11 within the thin-film transistor-formed region 13 per se. Thus, a detailed description of the thin-film transistor 10 and the integrated thin-film transistor 11 per se is omitted.

In the twelfth embodiment, the thin-film transistor-formed region 13 where the thin-film transistor 10 or the integrated transistor 11 is formed is set in the substrate 1 so as to fit in a region that approximately agrees with the outer shape of the thin-film transistor 10 or the integrated transistor 11 when viewed from the thickness direction of the substrate 1.

The thin-film transistor 10 or the integrated transistor 11 according to any one of the first to eleventh embodiments described above is provided within the thin-film transistor-formed region 13.

The connection wiring 12 is provided on the substrate 1. The connection wiring 12 extends to the outside of the thin-film transistor-formed region 13 where the thin-film transistor 10 is provided, when viewed from the thickness direction of the substrate 1. The connection wiring 12 is connected to each of the source electrode 5 and the drain electrode 6. The connection wiring 12 connected to one of the source electrode 5 and the drain electrode 6 is referred to as the first connection wiring 12a, and the connection wiring 12 connected to the other is referred to as the second connection wiring 12b.

The spread portion 14 spreading out of the thin-film transistor-formed region 13 when viewed from the thickness direction of the substrate 1 is provided on the substrate 1. The spread portion 14 is configured such that the gate electrode 3 and the gate insulating layer 4 that constitute the thin-film transistor 10 or the integrated transistor 11 provided within the thin-film transistor-formed region 13 spread out of the thin-film transistor-formed region 13 when viewed from the thickness direction of the substrate 1. The structure in which the gate electrode 3 and the gate insulating layer 4 are stacked is also referred to as a layered structure 15.

The spread portion 14 is configured to expose the connection wiring 12 without covering the connection wiring 12 when viewed from the thickness direction of the substrate 1. The gate electrode 3 comprised in the spread portion 14 is provided so as not to be electrically connected with the connection wiring 12.

Preferably, the spread portion 14 is configured to surround the periphery of the region outside the thin-film transistor-formed region 13 excluding the region where the connection wiring 12 is provided.

(Method for Manufacturing Thin-Film Transistor)

A method for manufacturing the thin-film transistor in the twelfth embodiment will be described. In the twelfth embodiment, the configuration examples of the first to eleventh embodiments as described above can be employed as the configuration of the thin-film transistor 10 and the integrated thin-film transistor 11 per se, as already described. There is no difference in the method for manufacturing the thin-film transistor per se, and a detailed description thereof is omitted.

“Step of Forming Gate Electrode and Connection Wiring”

The step of forming the connection wiring 12 can be performed at the same time by the same method as the step of forming the gate electrode 3 or the source electrode 5 and the drain electrode 6 on the substrate 1. The same material as the material of the gate electrode 3 or the source electrode 5 and the drain electrode 6 described above can be used as the material of the connection wiring 12.

To form the connection wiring 12, first, the material for forming the gate electrode 3 or the source electrode 5 and the drain electrode 6 as well as the connection wiring 12 is deposited. The thus formed layer can be formed not only in the thin-film transistor 10 or the integrated thin-film transistor 11 but also on the outside of the thin-film transistor-formed region 13 where the thin-film transistor 10 or the integrated thin-film transistor 11 is provided, by a patterning method such as photolithography method.

The leakage current and the parasitic capacity decrease as the area decreases where the gate electrode 3 overlaps the wiring provided within the thin-film transistor-formed region 13 with the gate insulating layer 4 interposed. It is therefore preferable to pattern the gate electrode 3 into such a shape as to minimize the area overlapped with the wiring provided within the thin-film transistor-formed region 13 with the gate insulating layer 4 interposed.

[Step of Forming Gate Insulating Layer]

The gate insulating layer 4 is formed in the same manner as in the foregoing embodiments. First, the first layer 4a comprised in the gate insulating layer 4 is formed. The first layer 4a can be formed in the same manner as in the foregoing embodiments. The first layer 4a is formed also in the region outside the thin-film transistor-formed region 13 excluding the region where the connection wiring 12 is provided.

Next, the second layer 4b that is a self-assembled monomolecular layer is formed so as to cover the first layer 4a in the same manner as in the foregoing embodiments. The second layer 4b is formed also in the region outside the thin-film transistor-formed region 13 excluding the region where the connection wiring 12 is provided.

The second layer 4b may be patterned so as to surround the periphery excluding the region where the connection wiring 12 (the first connection wiring 12a and the second connection wiring 12b) is provided, which is connected with each of the source electrode 5 and the drain electrode 6 and extends to the outside of the thin-film transistor-formed region 13.

For example, an aluminum oxide layer serving as the first layer 4a can be selectively formed on the surface of the gate electrode 3 of aluminum, for example, by performing oxygen plasma treatment. If a phosphonic acid derivative is used as the material of the second layer 4b that is a self-assembled monomolecular layer, the second layer 4b can be selectively formed on the surface of the first layer 4a. As a result, the second layer 4b that is a self-assembled monomolecular layer is patterned into a shape that overlaps the gate electrode 3. If a phosphonic acid derivative including an alkyl group with the number of carbon atoms of 10 or more is used, a self-assembled monomolecular layer with low surface free energy is formed in the region outside the thin-film transistor-formed region 13 where the thin-film transistor 10 or the integrated thin-film transistor 11 is provided. Thus, patterning can be performed in such a manner that the solution used when the semiconductor layer 7 is formed by a printing method such as the inkjet method does not spread out of the thin-film transistor-formed region 13 where the thin-film transistor 10 or the integrated thin-film transistor 11 is formed. Even when the semiconductor layer 7 spreads out of the thin-film transistor-formed region 13 where the thin-film transistor 10 or the integrated thin-film transistor 11 is provided due to misalignment of the coating position or other reasons, the gate electrode 3 is positioned immediately below the spreading material of the semiconductor layer 7, and thus leakage current due to the spreading material of the semiconductor layer 7 in the off state can be suppressed and increase of off-current can be prevented. Although the self-assembled monomolecular layer may spread to at least a partial region of the region outside the thin-film transistor-formed region 13 where the thin-film transistor 10 or the integrated thin-film transistor 11 is provided, it is preferable to surround the periphery of the region where the thin-film transistor 10 or the integrated thin-film transistor 11 is provided, to the possible extent, because if so, the possibility that the solution containing the material of the semiconductor layer 7 spreads is reduced more.

[Step of Forming Source Electrode and Drain Electrode]

Next, the source electrode 5 and the drain electrode 6 are formed collectively in the same manner as in the foregoing embodiments. The source electrode 5 and the drain electrode 6 are each connected to the connection wiring 12. That is, the source electrode 5 is formed so as to be electrically connected with one of the first connection wiring 12a and the second connection wiring 12b, and the drain electrode 6 is formed so as to be electrically connected to the one of the first connection wiring 12a and the second connection wiring 12b that is not connected with the source electrode 5.

According to the twelfth embodiment, the gate electrode 3 and the gate insulating layer 4 (the first layer 4a, the second layer 4b) have the spread portion 14 that spreads out of the thin-film transistor-formed region 13 when viewed from the thickness direction of the substrate 1, as described above. In the formation step, therefore, the second layer 4b provided outside the thin-film transistor-formed region 13 enables the semiconductor layer 7 to be formed within the transistor-formed region 13 in a self-alignment manner. Even when the semiconductor material adheres to an undesired place where the semiconductor material should not be applied, the gate electrode 3 is positioned immediately below the material of the semiconductor layer 7 because of the presence of the spread portion 14. As a result, the leakage current of the thin-film transistor 10 is suppressed, the off-current can be reduced, and reduction of the on/off ratio can be suppressed.

<Method for Increasing On-Current of Thin-Film Transistor>

A method for improving carrier transportability of the thin-film transistor in the present invention is a method for increasing on-current of the thin-film transistor by reducing the channel length by forming the channel so as to extend on the side surface of the insulating structure or the like, in other words, extend in the height direction of the insulating structure, and further reducing the thickness of the gate insulating layer, in the thin-film transistor of the present invention. Using this method is advantageous not only in that on-current is increased but also in that a high on/off ratio is achieved and driving at low voltage is enabled.

The thin-film transistor of the present invention can be suitably used for organic electroluminescent elements, electronic tags, and liquid crystal display elements. The “electronic tag” is a device configured with an IC for storing data and an antenna for transmitting/receiving data by radio. A device called a reader/writer can read information written in an electronic tag in a non-contact manner or write information into an electronic tag in a non-contact manner.

<Method for Verifying Effects>

The advantageous effects of the present invention can be supported with the results of experiments illustrated as Examples. The advantageous effects of the present invention can also be verified as the calculation results using an established simulation method.

For example, when device simulation software ATLAS available from Silvaco, Inc is used for calculation, the electrical characteristics of the thin-film transistor can be calculated by determining the conditions including the shape of the device, the work function of the electrode, the carrier mobility of the semiconductor layer, the doping position and concentration, the trap density, the dielectric constant, the effective density of state as well as the temperatures, and self-consistently solving the Poisson's equation and the transfer equation, and the characteristic values such as on-current, off-current and threshold voltage of the thin-film transistor can be obtained by calculation.

### EXAMPLES

Examples are provided below in order to describe the present invention in more details. The present invention, however, is not limited to these Examples.

### Example 1

A thin-film transistor having the structure described with reference to FIG. 3 (the third embodiment) was fabricated.

First, a glass substrate was prepared. A negative photoresist (SU-8) was spin-coated on the glass substrate and patterned by photolithography method to form 15 rectangular parallelepiped-shape insulating structures, each having a length of 100 μm in the longer direction, a length (width) of 10 μm in the shorter direction, and a height of 1.24 μm in the thickness direction of the substrate, such that they were spaced apart in parallel from each other with a distance of 10 μm between the adjacent insulating structures. About 20 nm thick aluminum was deposited by vacuum evaporation method on one side surface of the formed insulating structure from the direction at an angle of 45° relative to the surface of the glass substrate to form a gate electrode having a thickness of about 20 nm.

The glass substrate provided with the insulating structure and the gate electrode was subjected to oxygen plasma treatment for 3 minutes using an oxygen plasma apparatus under the conditions: output power 300 W; oxygen flow rate 50 sccm; and pressure about 30 Pa to form an aluminum oxide insulating film having a thickness of about 4 nm as the first layer that covers the surface of the gate electrode. In a solution prepared by dissolving octadecylphosphonic acid in isopropanol (2-propanol) at a concentration of 1 mM, the glass substrate provided with the insulating structure, the gate electrode, and the first layer was then immersed for 16 hours to form a self-assembled monomolecular layer having a thickness of about 2 nm on the surface of the first layer. The glass substrate was removed from the solution and then was baked on a hotplate at 70° C. for 5 minutes to form a second layer. About 10 nm thick gold was then deposited by evaporation to form a drain electrode on the top surface of the protrusion portion protruding from the substrate and a source electrode in the flat region one level lower than the protrusion portion. Each gate electrode and each drain electrode formed at each of the 15 insulating structures are electrically connected to the other gate electrodes and the other drain electrodes, respectively. The source electrodes formed in the flat regions are electrically connected to each other. The electrically connected gate electrodes, the electrically connected drain electrodes, and the electrically connected source electrodes are integrally operated as a gate electrode, a source electrode, and a drain electrode, respectively.

A compound of Formula (1-1) below that is an organic semiconductor material was dissolved in o-dichlorobenzene heated to 100° C. to prepare a solution with a compound concentration of 3 mg/mL.

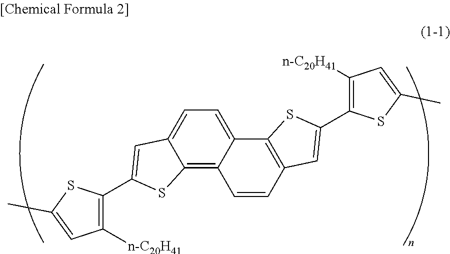

The resulting solution was then applied by spin coating method on the glass substrate on the side where the source electrode and the drain electrode were formed, to form a thin film of the compound of Formula (1-1) above.

Baking was then performed under a nitrogen atmosphere at 150° C. for 30 minutes to form a thin film of the compound above, that is, the organic semiconductor layer. Through the steps described above, a thin-film transistor was manufactured.

The manufactured thin-film transistor was cleaved with a focused ion beam apparatus (FIB), and the section was observed with an electron microscope. The channel length was 1.4 rim, and the channel width was 1.5 mm. The thickness of the gate insulating layer (a layered structure comprising the aluminum oxide layer as the first layer and the self-assembled monomolecular layer as the second layer) was about 6 nm.

The thin-film transistor manufactured as described above was operated as a p-type transistor.

The transistor characteristics were determined under the conditions in which the source voltage Vs was set to 0 V, the drain voltage Vd was set to −2 V, and the gate voltage Vg was changed from +1 V to −3.5 V. Table 1 shows the on-current density and the on/off ratio of the thin-film transistor as calculated from the transfer characteristic obtained through the measurement.

Furthermore, the transistor characteristics were determined under the conditions in which the source voltage Vs was set to 0 V, the gate voltage Vg was set to −3 V, and the drain voltage Vd was changed from 0 V to −3 V. Table 2 shows the rate of increase of the drain current value when the drain voltage Vd is −3 V to the current value when the drain voltage Vd is −2 V, as calculated from the output characteristic obtained through the measurement. It can be said that the thin-film transistor can be operated with better characteristics as the rate of increase of the drain current value decreases.

### Example 2

An n-type silicon substrate was prepared as a substrate. Through the step of forming a mask pattern and the dry etching step using this mask pattern, 15 rectangular parallelepiped-shape protrusion portions, each having a length of 100 μm in the longer direction, a width of 10 μm in the shorter direction, and a height of 0.86 μm in the thickness direction of the substrate, were formed on the surface of the n-type silicon substrate such that they were spaced apart in parallel from each other with a distance of 10 μm between the adjacent protrusion portions. The n-type silicon substrate with the protrusion portions was then subjected to thermal oxidation to form a silicon oxide film having a thickness of about 200 nm on the surface of the substrate with the protrusion portions. Next, about 20 nm think aluminum was deposited by vacuum evaporation on one side surface of the protrusion portion from the diagonal direction relative to the surface of the substrate to form a gate electrode. Subsequently, the n-type silicon substrate with the gate electrode was subjected to oxygen plasma treatment for 3 minutes using an oxygen plasma apparatus under the conditions: output power 300 W; oxygen flow rate 50 sccm; and pressure about 30 Pa to form an aluminum oxide insulating film having a thickness of about 4 nm as the first layer of the gate insulating layer on the surface of the gate electrode. In a solution prepared by dissolving octadecylphosphonic acid in isopropanol (2-propanol) at a concentration of 1 mM, the n-type silicon substrate with the gate electrode and the first layer was then immersed for 16 hours to form a self-assembled monomolecular layer having a thickness of about 2 nm on the surface of the first layer. The n-type silicon substrate was removed from the solution and then was baked on the hotplate at 70° C. for 5 minutes to form a second layer. About 10 nm thick gold was then deposited by evaporation on the surface of the n-type silicon substrate with the second layer to form a drain electrode on the top surface of the protrusion portion protruding from the substrate and a source electrode in the flat region one level lower than the protrusion portion. Each gate electrode and each drain electrode formed at each of the 15 protrusion portions are electrically connected to the other gate electrodes and the other drains electrode, respectively. The source electrodes formed in the flat regions are electrically connected to each other. The electrically connected gate electrodes, the electrically connected drain electrodes, and the electrically connected source electrodes are integrally operated as a gate electrode, a source electrode, and a drain electrode, respectively.

The compound represented by Formula (1-1) above that is an organic semiconductor material was dissolved in o-dichlorobenzene heated to 100° C. to prepare a solution with a compound concentration of 3 mg/mL.

The resulting solution was then applied by spin coating method on the n-type silicon substrate on the side where the source electrode and the drain electrode were formed, to form a thin film of the compound represented by Formula (1-1) above. Baking was then performed under a nitrogen gas atmosphere at 150° C. for 30 minutes to form a thin film of the compound above, that is, the organic semiconductor layer. Through the steps described above, a thin-film transistor was manufactured.

The manufactured thin-film transistor was cleaved with the FIB, and the section was observed with the electron microscope. The channel length was 0.9 rim, and the channel width was 2 mm. The thickness of the gate insulating layer (a layered structure comprising the aluminum oxide layer as the first layer and the self-assembled monomolecular layer as the second layer) was about 6 nm.

The thin-film transistor manufactured as described above was operated as a p-type transistor.

The transistor characteristics were determined under the conditions in which the source voltage Vs was set to 0 V, the drain voltage Vd was set to −2.0 V, and the gate voltage Vg was changed from +0.5 V to −3.5 V. Table 1 shows the on-current density and the on/off ratio of the thin-film transistor as calculated from the transfer characteristic obtained through the measurement. Furthermore, the transistor characteristics were determined under the conditions in which the source voltage Vs was set to 0 V, the gate voltage Vg was set to −3 V, and the drain voltage Vd was changed from 0 V to −3 V. Table 2 shows the rate of increase of the drain current value when the drain voltage Vd is −3 V to the current value when the drain voltage Vd is −2 V, as calculated from the output characteristic obtained through the measurement.

### Comparative Example 1

A thin-film transistor was manufactured, in which the gate insulating layer 4 was formed of a single film in the structure described with reference to FIG. 2-1 and FIG. 2-2 (the second embodiment).

A negative photoresist (SU-8) was applied on a PEN substrate by spin coating method and patterned by photolithography method to form 15 rectangular parallelepiped-shape insulating structures, each having a length of 100 μm in the longer direction, a width of 10 μm in the shorter direction, and a height of 2.6 μm in the thickness direction of the substrate such that they were spaced apart in parallel from each other with a distance of 10 μm between the adjacent insulating structures. A gate electrode comprising a 5 nm-thick Ti layer, a 15 nm-thick Pt layer, and a 5 nm-thick Ti layer was formed on the side surface of the formed insulating structure by sputtering method at an angle of 45° and at an angle of 135° relative to the surface of the PEN substrate. A 275 nm thick insulating material (dix-SR, manufactured by DISCO) was then deposited by evaporation on the entire surface of the PEN substrate on the side where the gate electrode was formed, to serve as a gate insulating layer. The PEN substrate having the insulating structure, the gate electrode, and the gate insulating layer was thus formed. About 10 nm thick gold was then deposited by evaporation on the surface of the PEN substrate with the gate insulating layer to form a drain electrode on the top surface of the protrusion portion protruding from the PEN substrate and a source electrode in the flat region one level lower than the protrusion portion. Each gate electrode and each drain electrode formed at each of the 15 protrusion portions are electrically connected to the other gate electrodes and the other drain electrodes, respectively. The source electrodes formed in the flat regions are electrically connected to each other. The electrically connected gate electrodes, the electrically connected drain electrodes, and the electrically connected source electrodes are integrally operated as a gate electrode, a source electrode, and a drain electrode, respectively.

The compound represented by Formula (1-1) above that is an organic semiconductor material was dissolved in o-dichlorobenzene heated to 100° C. to prepare a solution with a compound concentration of 1 mg/mL.

The resulting solution was then applied by spin coating on the PEN substrate on the side where the source electrode and the drain electrode were formed, to form a thin film of the compound represented by Formula (1-1) above.

Baking was then performed under a nitrogen gas atmosphere at 100° C. for 30 minutes to form a thin film of the compound above, that is, the organic semiconductor layer. Through the steps described above, a thin-film transistor was manufactured.

The thin film of the compound functions as an organic semiconductor layer.

The manufactured thin-film transistor was cleaved with the FIB, and the section was observed with the electron microscope. The channel length was 2.6 rim, and the channel width was 6.5 mm. The thickness of the gate insulating layer was 275 nm.

The thin-film transistor manufactured as described above was operated as a p-type transistor.

The transistor characteristics were determined under the conditions in which the source voltage Vs was set to 0 V, the drain voltage Vd was set to −20 V, and the gate voltage Vg was changed from +20 V to −20 V. Table 1 shows the on-current density and the on/off ratio of the thin-film transistor as calculated from the transfer characteristic obtained through the measurement. Furthermore, the transistor characteristics were determined under the conditions in which the source voltage Vs was set to 0 V, the gate voltage Vg was set to −15 V, and the drain voltage Vd was changed from 0 V to −20 V. Table 2 shows the rate of increase of the drain current value when the drain voltage Vd is −20 V to the current value when the drain voltage Vd is −18 V, as calculated from the output characteristic obtained through the measurement.

### Comparative Example 2

An n-type silicon substrate doped with an impurity at a high concentration was manufactured as a substrate. This substrate is a component that also serves as a gate electrode.

Through the step of forming a mask pattern and dry etching using this mask pattern, 15 rectangular parallelepiped-shape protrusion portions, each having a length of 100 μm in the longer direction, a width of 10 μm in the shorter direction, and a height of 4.0 μm in the thickness direction of the substrate, were formed on the surface of the n-type silicon substrate such that they were spaced apart in parallel from each other with a distance of 10 μm between the adjacent protrusion portions. A gate insulating layer comprising the first layer and the second layer was then formed. Specifically, the n-type silicon substrate having the protrusion portion was subjected to thermal oxidation to form a silicon oxide film as the first layer having a thickness of about 200 nm on the surface of the substrate with the protrusion portion. Vapor treatment with decyltriethoxysilane was then performed in an oven at 120° C. for 1 hour to form a monomolecular layer of decyltriethoxysilane as the second layer on the surface of the silicon oxide film. About 10 nm thick gold was then deposited by evaporation on the surface of the n-type silicon substrate on the side where the monomolecular layer of decyltriethoxysilane was formed, to form a drain electrode on the top surface of the protrusion portion protruding from the substrate and a source electrode in the flat region one level lower than the protrusion portion. Each gate electrode and each drain electrode formed at each of the 15 protrusion portions are electrically connected to the other gate electrodes and the other drain electrodes, respectively. The source electrodes formed in the flat regions are electrically connected to each other. The electrically connected gate electrodes, the electrically connected drain electrodes, and the electrically connected source electrodes are integrally operated as a gate electrode, a source electrode, and a drain electrode, respectively.

The compound represented by Formula (1-1) above that is an organic semiconductor material was dissolved in o-dichlorobenzene to yield a solution with a compound concentration of 1 mg/mL, and the solution was passed through a membrane filter to prepare a coating liquid.

The resulting coating liquid was then applied by spin coating method on the n-type silicon substrate on the side where the source electrode and the drain electrode were formed, to form a thin film of the compound represented by Formula (1-1). Baking was then performed under a nitrogen gas atmosphere at 150° C. for 30 minutes to form a thin film of the compound above, that is, the organic semiconductor layer. Through the steps described above, a thin-film transistor was manufactured.

The manufactured thin-film transistor was cleaved with the FIB and observed with the electron microscope. The channel length was 4 rim, and the channel width was 1.5 mm. The thickness of the gate insulating layer (a layered structure comprising the silicon oxide film as the first layer and the decyltriethoxysilane monomolecular layer as the second layer) was 200 nm.

The thin-film transistor manufactured as described above was operated as a p-type transistor.

The transistor characteristics were determined under the conditions in which the source voltage Vs was set to 0 V, the drain voltage Vd was set to −20 V, and the gate voltage Vg was changed from +20 V to −20 V. Table 1 shows the on-current density and the on/off ratio of the thin-film transistor as calculated from the transfer characteristic obtained through the measurement. Furthermore, the transistor characteristics were determined under the conditions in which the source voltage Vs was set to 0 V, the gate voltage Vg was set to −15 V, and the drain voltage Vd was changed from 0 V to −20 V. Table 2 shows the rate of increase of the drain current value when the drain voltage Vd is −20 V to the current value when the drain voltage Vd is −18 V, as calculated from the output characteristic obtained through the measurement.

TABLE 1

| | THICKNESS OF | GATE | DRAIN | CHANNEL | ON-CURRENT | |
|---|---|---|---|---|---|---|
| | GATE INSULATING | VOLTAGE | VOLTAGE | LENGTH | DENSITY | |
| | LAYER (nm) | (V) | (V) | (μm) | (mA/cm²) | ON/OFF RATIO |
| EXAMPLE 1 | 6 | +1.0 to −3.5 | −2.0 | 1.4 | 38.5 | 3 × 10⁵ |
| EXAMPLE 2 | 6 | +0.5 to −3.5 | −2.0 | 0.9 | 45.2 | 4 × 10⁴ |
| COMPARATIVE | 275 | +20 to −20 | −20 | 2.6 | 41.8 | 8 × 10¹ |
| EXAMPLE 1 | | | | | | |
| COMPARATIVE | 200 | +20 to −20 | −20 | 4.0 | 8.64 | 6 × 10³ |
| EXAMPLE 2 | | | | | | |

TABLE 2

| | | | | | RANGE OF DRAIN |
|---|---|---|---|---|---|
| | | | | RATE OF | VOLTAGE FOR |
| | THICKNESS OF | | | INCREASE OF | CALCULATING RATE |
| | GATE | GATE | DRAIN | DRAIN | OF INCREASE OF |
| | INSULATING | VOLTAGE | VOLTAGE | CURRENT | DRAIN CURRENT |
| | LAYER (nm) | (V) | (V) | VALUE (%) | VALUE (V) |
| EXAMPLE 1 | 6 | −3.0 | 0 to −3.0 | 4.0 | −2.0 to −3.0 |
| EXAMPLE 2 | 6 | −3.0 | 0 to −3.0 | 3.4 | −2.0 to −3.0 |
| COMPARATIVE | 275 | −15 | 0 to −20 | 26.6 | −18 to −20 |
| EXAMPLE 1 | | | | | |
| COMPARATIVE | 200 | −15 | 0 to −20 | 12.1 | −18 to −20 |
| EXAMPLE 2 | | | | | |

The thin-film transistors (integrated thin-film transistors) having the vertical transistor structure manufactured in Examples 1 and 2 have a short channel length and thus achieve a high on-current density. In addition, because the thickness of the gate insulating layer is small, the short channel effects do not occur and a high on/off ratio is achieved.

The thin-film transistors manufactured in Examples 1 and 2 also have sufficiently low drive voltages. In addition, the rate of increase of the drain current value is small, and favorable saturation characteristics are obtained.

By contrast, although the thin-film transistor manufactured in Comparative Example 1 has a high on-current density, the on/off ratio is low and the drive voltage is high, because the gate insulating layer is thick. The thin-film transistor manufactured in Comparative Example 2 has a relatively large on/off ratio, but the on-current density is small and the drive voltage is high. In the thin-film transistors manufactured in Comparative Examples 1 and 2 when compared with the thin-film transistors manufactured in Examples 1 and 2, because the range of the drain voltage for calculating the rate of increase of drain current is small relative to the drive voltage and because the gate voltage is lower than the drain voltage, current is more likely to be saturated. Nevertheless, the rate of increase of drain current is 10% or more and the drain current is hardly saturated.

### Comparative Example 3

A thin-film transistor having a lateral structure was manufactured.

A glass substrate was prepared as a substrate. About 20 nm thick aluminum was deposited by vacuum evaporation on the glass substrate to serve as a gate electrode. The glass substrate with the gate electrode was then subjected to oxygen plasma treatment for 3 minutes using an oxygen plasma apparatus under the conditions: output power 300 W; oxygen flow rate 30 sccm; and pressure about 24 Pa to form an aluminum oxide insulating film having a thickness of about 4 nm as the first layer on the surface of the gate electrode. In a solution prepared by dissolving octadecylphosphonic acid in isopropanol (2-propanol) at a concentration of 1 mM, the glass substrate with the gate electrode and the first layer was then immersed for 16 hours to form a self-assembled monomolecular layer having a thickness of about 2 nm on the surface of the first layer. The immersed glass substrate was removed from the solution and then was baked on the hotplate at 70° C. for 5 minutes to form a second layer. About 50 nm thick gold was then deposited by evaporation on the surface of the glass substrate on the side where the second layer was formed, to form a source electrode and a drain electrode.

The compound represented by Formula (1-1) above that is an organic semiconductor material was dissolved in o-dichlorobenzene to yield a solution with a compound concentration of 3 mg/mL, and the solution was passed through the membrane filter to prepare a coating liquid.

The resulting coating liquid was then applied by spin coating method on the glass substrate on the side where the source electrode and the drain electrode were formed, to form a thin film of the compound represented by Formula (1-1) above. Baking was then performed under a nitrogen gas atmosphere at 150□C for 30 minutes to form a thin film of the compound above, that is, the organic semiconductor layer. Through the steps described above, a thin-film transistor was manufactured.

According to the observation of the section of the manufactured thin-film transistor with an optical microscope, the channel length was 20 μm and the channel width was 2 mm. The thickness of the gate insulating layer (a layered structure comprising the aluminum oxide insulating layer as the first layer and the self-assembled monomolecular layer as the second layer) was about 6 nm.

The thin-film transistor manufactured as described above was operated as a p-type transistor. The transistor characteristics were determined under the conditions in which the source voltage Vs was set to 0 V, the drain voltage Vd was set to −2.0 V, and the gate voltage Vg was changed from 0 to −3.0 V. Table 3 shows the on-current density and the on/off ratio of the thin-film transistor as calculated from the transfer characteristic obtained through the measurement. Furthermore, the transistor characteristics were determined under the conditions in which the source voltage Vs was set to 0 V, the gate voltage Vg was set to −3 V, and the drain voltage Vd was changed from 0 to −3 V. Table 4 shows the rate of increase of the drain current value when the drain voltage Vd is −3 V to the current value when the drain voltage Vd is −2 V, as calculated from the current-voltage characteristic obtained through the measurement.

Comparative Example 3 is a lateral thin-film transistor and cannot achieve a short channel length and, therefore, the on-current density is small.

TABLE 3

| | THICKNESS OF | GATE | DRAIN | CHANNEL | ON-CURRENT | |
|---|---|---|---|---|---|---|
| | INSULATING | VOLTAGE | VOLTAGE | LENGTH | DENSITY | |
| | LAYER (nm) | (V) | (V) | (μm) | (mA/cm²) | ON/OFF RATIO |
| COMPARATIVE | 6 | 0 to −3.0 | −2.0 | 20 | 2.72 | 9 × 10⁴ |
| EXAMPLE 3 | | | | | | |

TABLE 4

| | | | | | RANGE OF DRAIN |
|---|---|---|---|---|---|
| | | | | RATE OF | VOLTAGE FOR |
| | | | | INCREASE OF | CALCULATING RATE |
| | THICKNESS OF | GATE | DRAIN | DRAIN | OF INCREASE OF |
| | INSULATING | VOLTAGE | VOLTAGE | CURRENT | DRAIN CURRENT |
| | LAYER (nm) | (V) | (V) | VALUE (%) | VALUE (V) |
| COMPARATIVE | 6 | −3.0 | 0 to −3.0 | 0.4 | −2.0 to −3.0 |
| EXAMPLE 3 | | | | | |

### Examples 3 to 6

In the thin-film transistors (integrated thin-film transistors) having the structures described with reference to FIG. 2-1 and FIG. 2-2 (the second embodiment: Example 3), FIG. 5 (the fifth embodiment: Example 4), FIG. 8 (the eighth embodiment: Example 5), and FIG. 9 (the ninth embodiment: Example 6), the on/off ratio, the on-current, and the rate of increase of the drain current value were determined by two-dimensional device simulation. In the simulation, ATLAS from Silvaco, Inc. was used. The relative dielectric constant of the gate insulating layer 4 was set to 3.9, which is within the range of the value attained when the layered structure comprising the first layer 4a that is a silicon oxide film and the second layer 4b that is a self-assembled monomolecular layer is used. With a thickness of 6 nm or more, the gate insulating layer 4 has good insulating characteristics and functions as the gate insulating layer 4 of the thin-film transistor. Based on this, simulation of the transistor characteristics was conducted with the gate insulating layer 4 having a thickness set to 10 nm. The temperature was set to 300 K, the thickness of the semiconductor layer 7 was set to 50 nm, the relative dielectric constant of the organic semiconductor material comprised in the semiconductor layer 7 was set to 3, the electron affinity of the organic semiconductor material was set to 2.8 eV, the bandgap of the organic semiconductor material was set to 2.2 eV, the hole carrier mobility of the organic semiconductor material was set to 0.15 cm²/Vs, the channel length was set to 0.5 rim, the channel width was set to 25 mm, the effective density of state of the valence band and the conduction band was set to 10²⁰ cm⁻³, and the work function of the electrode was set to 5.0 eV. The transfer characteristic was simulated with the source voltage Vs of 0 V, the drain voltage Vd of −40 V, and the gate voltage Vg changed from +20 V to −40 V.

Table 5 shows the on-current and the on/off ratio calculated from the transfer characteristic of the transistor obtained by the simulation. The on-current is a current value when the gate voltage Vg is −40 V, and the on/off ratio is the ratio between the current value when the gate voltage Vg is −40 V and the current value when the gate voltage Vg is +20 V. In addition, the drain current values were calculated with the source voltage Vs of 0 V, the gate voltage Vg of −10 V, and the drain voltage Vd changed in the range from 0 V to −40 V. Table 6 shows the rate of increase of the drain current value when the drain voltage Vd is −40 V to the drain current value when the drain voltage Vd is −20 V. When the rate of increase of the drain current value is smaller, the thin-film transistor is operated more favorably. In the simulation, the structure obtained by extracting the vicinity of the side surfaces 2a of one insulating structure 2 was used. Thus, the simulation results of the on/off ratio, the on-current, and the drain current value increase rate of the thin-film transistors having the structures illustrated in FIG. 1-1 and FIG. 1-2, FIG. 3, and FIG. 4 are the same as the simulation results of the thin-film transistor having the structure illustrated in FIG. 2-1 and FIG. 2-2.

### Comparative Examples 4 to 7

In the thin-film transistors having the structures described with reference to FIG. 2-1 and FIG. 2-2 (the second embodiment: Comparative Example 4), FIG. 5 (the fifth embodiment: Comparative Example 5), FIG. 8 (the eighth embodiment: Comparative Example 6), and FIG. 9 (the ninth embodiment: Comparative Example 7), simulation with the gate insulating layer 4 having a thickness set to 200 nm was conducted as Comparative Examples 4 to 7 in the same manner as in Examples 3 to 6.

Table 5 shows the on-current and the on/off ratio calculated from the transfer characteristic of the thin-film transistor obtained by the simulation, and Table 6 shows the rate of increase of drain current.

TABLE 5

| | THICKNESS OF | ON- | |
|---|---|---|---|
| | GATE INSULATING | CURRENT | ON/OFF |
| | LAYER (nm) | (A) | RATIO |
| EXAMPLE 3 | 10 | 2.08 | 7.4 × 10¹⁵ |
| COMPARATIVE | 200 | 0.13 | 78 |
| EXAMPLE 4 | | | |
| EXAMPLE 4 | 10 | 0.90 | 4.0 × 10²⁰ |
| COMPARATIVE | 200 | 0.11 | 9.0 × 10⁶ |
| EXAMPLE 5 | | | |
| EXAMPLE 5 | 10 | 1.04 | 1.4 × 10¹⁵ |
| COMPARATIVE | 200 | 0.12 | 8.4 × 10⁵ |
| EXAMPLE 6 | | | |
| EXAMPLE 6 | 10 | 2.08 | 5.7 × 10¹⁵ |
| COMPARATIVE | 200 | 0.14 | 9.1 × 10⁸ |
| EXAMPLE 7 | | | |

TABLE 6

| | THICKNESS OF | RATE OF |
|---|---|---|
| | GATE INSULATING | INCREASE OF DRAIN |
| | LAYER (nm) | CURRENT VALUE (%) |
| EXAMPLE 3 | 10 | 5.9 |
| COMPARATIVE | 200 | 138 |
| EXAMPLE 4 | | |
| EXAMPLE 4 | 10 | 12.6 |
| COMPARATIVE | 200 | 141 |
| EXAMPLE 5 | | |
| EXAMPLE 5 | 10 | 18.2 |
| COMPARATIVE | 200 | 141 |
| EXAMPLE 6 | | |
| EXAMPLE 6 | 10 | 11.9 |
| COMPARATIVE | 200 | 122 |
| EXAMPLE 7 | | |

The on/off ratio is increased in the simulation results in Examples 3 to 6 when compared with the simulation results of the thin-film transistors in Comparative Examples 4 to 7.

The on-current is also increased and thus the voltage for achieving a predetermined current value is also reduced, showing that the drive voltage is reduced. The rate of increase of the drain current value is also reduced, showing that the thin-film transistors according to Examples 3 to 6 have favorable characteristics.

### Example 7

First, a glass substrate was prepared as a substrate. A negative photoresist (SU-8) was spin-coated on the glass substrate and patterned by photolithography method to form a rectangular parallelepiped-shape insulating structure having a length of 100 μm in the longer direction, a length of 50 μm (width) in the shorter direction, and a height of 0.95 μm in the thickness direction of the glass substrate. An about 25 nm thick aluminum layer was deposited by vacuum evaporation from the direction at an angle of 45° relative to the surface of the glass substrate, on one of the side surfaces having a side extending in the longer direction of the formed insulating structure. Through a photolithography method, the aluminum layer deposited by evaporation in the unnecessary region was patterned by etching and removed to form a gate electrode having a thickness of about 25 nm. Here, the gate electrode was patterned not only in the thin-film transistor-formed region where the thin-film transistor is formed but also to have a spread portion that spreads out of the thin-film transistor-formed region and surround the periphery of the thin-film transistor-formed region when viewed from the thickness direction of the substrate.

The glass substrate provided with the insulating structure and the gate electrode was then subjected to oxygen plasma treatment for 10 minutes using an oxygen plasma apparatus under the conditions: output power 300 W; oxygen flow rate 20 sccm; and pressure about 20 Pa to form an aluminum oxide insulating film having a thickness of about 4 nm as the first layer that covers the surface of the gate electrode. In a solution prepared by dissolving tetradecylphosphonic acid in isopropanol (2-propanol) at a concentration of 1 mM, the glass substrate with the insulating structure, the gate electrode and the first layer was then immersed for 16 hours to form a self-assembled monomolecular layer having a thickness of about 2 nm on the surface of the first layer. The glass substrate was removed from the solution and then was baked on the hotplate at 70° C. for 5 minutes to form a second layer. The first layer and the second layer were formed so as to expose the connection wiring. About 25 nm thick gold for forming a source electrode and a drain electrode was then deposited by evaporation to form a drain electrode on the top surface of the protrusion portion protruding from the substrate and a source electrode in the flat region one level lower than the protrusion portion. Simultaneously with the formation of the source electrode and the drain electrode by patterning, the connection wiring extending to the outside of the thin-film transistor-formed region was formed.

The compound represented by Formula (5-1) below that is an organic semiconductor material was dissolved in mesitylene heated to 100° C. to prepare a solution with a compound concentration of 1.0 wt %.

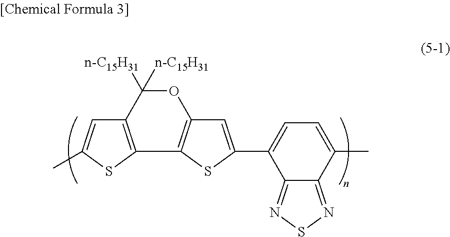

The resulting solution was then deposited by the inkjet method on the glass substrate on the side where the source electrode and the drain electrode were formed, to form a thin film of the compound of Formula (5-1) above. In doing so, the amount of the solution spreading to the outside of the thin-film transistor was suppressed, resulting in favorable patterning, because the periphery of the thin-film transistor except the wiring was surrounded with the liquid repellent self-assembled monomolecular layer of tetradecylphosphonic acid. Baking was thereafter performed under a nitrogen gas atmosphere at 150° C. for 30 minutes to form a thin film of the compound above, that is, the organic semiconductor layer. Through the steps described above, a thin-film transistor was manufactured.

According to the observation of the manufactured thin-film transistor with the electron microscope, the channel length was 0.9 μm and the channel width was 100 μm.

One of the thin-film transistors manufactured as described above was operated as a p-type transistor. The transistor characteristics were determined under the conditions in which the source voltage Vs was set to 0 V, the drain voltage Vd was set to −3 V, and the gate voltage Vg was changed from 0 V to −4 V. Table 7 below shows the on-current density and the on/off ratio of the thin-film transistor as calculated from the transfer characteristic obtained through the measurement.

### Comparative Example 8

A thin-film transistor was manufactured in the same manner as in Example 7 except that the gate electrode and the gate insulating film were formed by patterning only in the thin-film transistor-formed region. When the solution of the compound represented by Formula (5-1) above was applied by the inkjet method, the applied solution overflowed to the outside of the thin-film transistor-formed region because the self-assembled monomolecular layer of tetradecylphosphonic acid was not formed on the periphery of the thin-film transistor-formed region.

One of the manufactured thin-film transistors was operated as a p-type transistor. The transistor characteristics were determined under the conditions in which the source voltage Vs was set to 0 V, the drain voltage Vd was set to −3 V, and the gate voltage Vg was changed from 0 V to −4 V. Table 7 below shows the on-current density and the on/off ratio of the thin-film transistor as calculated from the transfer characteristic obtained through the measurement.

As is clear from Table 7, it can be understood that the higher on/off ratio is obtained in Example 7 than in Comparative Example 8. The reason for this is as follows. In Example 7, because the self-assembled monomolecular layer made of tetradecylphosphonic acid with a liquid repellent surface is formed so as to surround the source electrode and the drain electrode, the amount of overflow of the solution containing the semiconductor material from the thin-film transistor-formed region can be reduced in forming the semiconductor layer by the inkjet method when compared with Comparative Example 8 in which the periphery of the thin-film transistor-formed region is not surrounded with the self-assembled monomolecular layer made of tetradecylphosphonic acid, so that leakage current due to the semiconductor material overflowing to the outside of the thin-film transistor-formed region can be suppressed, and that the off-current can be reduced. As for the region where the semiconductor material overflows, the overflowing semiconductor material is depleted during off because of the presence of the gate electrode under the semiconductor material, thereby reducing the off-current.

TABLE 7

| | SPREAD PORTION | ON/OFF RATIO |
|---|---|---|
| EXAMPLE 7 | PRESENT | 2.4 × 10⁵ |
| COMPARATIVE | ABSENT | 1.1 × 10³ |
| EXAMPLE 8 | | |

### EXPLANATIONS OF LETTERS OR NUMERALS

1 substrate
1a first main surface
1b second main surface
2 insulating structure
2a, 4aa, 4ba(4A), 7a, 8a side surface
2b, 3b, 4B, 5a, 7b top surface
2A base portion
2B comb tooth portion
3 gate electrode
4 gate insulating layer
4a first layer
4b second layer
5 source electrode
6 drain electrode
7 semiconductor layer
8 protrusion portion
10 thin-film transistor
11 integrated thin-film transistor
12 connection wiring
12a first connection wiring
12b second connection wiring
13 thin-film transistor-formed region
14 spread portion
15 layered structure
CR channel region

1. A thin-film transistor provided on a substrate, comprising:
a column-shaped protrusion portion that protrudes from a main surface of the substrate, the protrusion portion having a side surface extending in a direction that approximately corresponds to a thickness direction of the substrate;
a gate insulating layer with a thickness of 50 nm or less, at least part of the gate insulating layer being provided in a channel region extending along the side surface, the gate insulating layer comprising a first layer that is a metal oxide layer, a metal nitride layer, a silicon oxide layer, or a silicon nitride layer and a second layer that is a self-assembled monomolecular layer;
a gate electrode in contact with the gate insulating layer;
a source electrode and a drain electrode isolated from each other, at least part of one of the source electrode and the drain electrode being provided to overlap the protrusion portion when viewed from the thickness direction of the substrate and the other being provided in a region that does not overlap the protrusion portion or the one electrode when viewed from the thickness direction of the substrate; and
a semiconductor layer in contact with at least part of the source electrode, at least part of the drain electrode, and at least part of the gate insulating layer in the channel region directly or with a functional layer interposed.

2. The thin-film transistor according to claim 1, wherein
the protrusion portion is an insulating structure provided on the substrate,
the gate electrode covers at least part of a side surface of the insulating structure,
the gate insulating layer covers the gate electrode,
the source electrode and the drain electrode are in contact with the gate insulating layer, and
the semiconductor layer covers the source electrode and the drain electrode as well as the gate insulating layer.

3. The thin-film transistor according to claim 1, wherein
the protrusion portion is an insulating structure provided on the substrate,
the gate electrode covers the insulating structure,
the gate insulating layer covers the gate electrode,
the semiconductor layer covers the gate insulating layer, and the source electrode and the drain electrode are in contact with the semiconductor layer.

4. The thin-film transistor according to claim 1, wherein
the protrusion portion is a gate electrode provided on the substrate, and
the gate insulating layer covers the gate electrode.

5. The thin-film transistor according to claim 1, wherein
the protrusion portion is a semiconductor layer provided on the substrate, the gate insulating layer is provided to cover at least part of a side surface of the semiconductor layer, and the gate electrode covers the gate insulating layer.

6. A thin-film transistor provided on a substrate, comprising:
a column-shaped protrusion portion that protrudes from a main surface of the substrate, the protrusion portion having a side surface with a shorter direction that approximately corresponds to a thickness direction of the substrate and a longer direction that is a direction orthogonal to the thickness direction of the substrate;
a source electrode and a drain electrode isolated from each other, one of the source electrode and the drain electrode being provided to overlap the protrusion portion when viewed from the thickness direction of the substrate and the other being provided in a region that does not overlap the protrusion portion or the one electrode when viewed from the thickness direction of the substrate;
a semiconductor layer that covers the source electrode and the drain electrode as well as the side surface exposed from the source electrode and the drain electrode;
a gate insulating layer with a thickness of about 50 nm or less that covers the semiconductor layer, the gate insulating layer comprising a first layer that is a metal oxide layer, a metal nitride layer, a silicon oxide layer, or a silicon nitride layer and a second layer that is a self-assembled monomolecular layer; and
a gate electrode that is in contact with the gate insulating layer and extends across the protrusion portion.

7. The thin-film transistor according to claim 6, wherein the semiconductor layer covers the substrate and the protrusion portion provided on the substrate, the source electrode and the drain electrode are in contact with the semiconductor layer, and the gate insulating layer covers the source electrode and the drain electrode as well as the semiconductor layer exposed from the source electrode and the drain electrode.

8. The thin-film transistor according to claim 1, wherein the column-shaped protrusion portion, the gate electrode, or the semiconductor layer is formed through a patterning step by a photolithography method or a nanoimprinting method.

9. The thin-film transistor according to claim 1, wherein the gate electrode contains metal or silicon, and the metal oxide layer, the metal nitride layer, the silicon oxide layer, and the silicon nitride layer as the first layer are layers formed by subjecting the metal or silicon contained in the gate electrode to plasma treatment or anodic oxidation treatment.

10. The thin-film transistor according to claim 1, wherein the second layer is a film of a compound that comprises a saturated hydrocarbon group with the number of carbon atoms of 10 or more, or a saturated hydrocarbon group with the number of carbon atoms of 10 or more and optionally having a substituent, and can be bonded to the first layer.

11. The thin-film transistor according to claim 1, wherein the second layer is a film of a phosphonic acid derivative, a film of a trichlorosilane derivative, or a film of triethoxysilane derivative.

12. The thin-film transistor according to claim 1, wherein the gate electrode contains aluminum.

13. An integrated thin-film transistor comprising a plurality of thin-film transistors of claim 1 arranged on the substrate so as to be spaced apart from each other, wherein each gate electrode, each source electrode, and each drain electrode of each of the thin-film transistors are electrically connected to other gate electrodes, other source electrodes, and other drain electrodes, respectively, and the thin-film transistors are integrally operated as a single transistor.

14. The thin-film transistor according to claim 1, further comprising connection wiring that extends outside a thin-film transistor-formed region where the thin-film transistor is provided when viewed from the thickness direction of the substrate and is connected with each of the source electrode and the drain electrode, wherein the gate electrode and the gate insulating layer have a spread portion that spreads out of the thin-film transistor-formed region when viewed from the thickness direction of the substrate.
